(19) United States
(12) Patent Application Publication
(10) Pub. No.: US 2024/0429297 A1
(43) Pub. Date: Dec. 26, 2024

(54) SEMICONDUCTOR DEVICE

(71) Applicant: ROHM CO., LTD., Kyoto-shi (JP)

(72) Inventors: Manabu YANAGIHARA, Kyoto-shi (JP); Ryoichi MAKINO, Kyoto-shi (JP); Hirotaka OTAKE, Kyoto-shi (JP)

(73) Assignee: ROHM CO., LTD., Kyoto-shi (JP)

(21) Appl. No.: 18/827,900

(22) Filed: Sep. 9, 2024

Related U.S. Application Data
(63) Continuation of application No. PCT/JP2023/006800, filed on Feb. 24, 2023.

(30) Foreign Application Priority Data
Mar. 15, 2022 (JP) 2022-040038

(51) Int. Cl. H01L 29/423; H01L 29/20; H01L 29/417; H01L 29/47; H01L 29/778

(52) U.S. Cl. CPC H01L 29/42376; H01L 29/2003; H01L 29/41775; H01L 29/475; H01L 29/778

(57) ABSTRACT

This semiconductor device includes first and second gate portions formed by a semiconductor layer containing acceptor impurities. First and second gate electrodes are arranged on parts of the first and second gate portions, respectively. The upper surface of the first gate portion includes a first side-space region located toward a source electrode and extending over length L1 and a second side-space region located toward a first drain electrode and extending over length L2. The upper surface of the second gate portion includes a third side-space region located toward the source electrode and extending over length L3 and a fourth side-space region located toward a second drain electrode and extending over length L4. The lengths L1 and L2 satisfy the relationship of L1>L2, and the lengths L3 and L4 satisfy the relationship of L3>L4.

### CROSS-REFERENCE TO RELATED APPLICATIONS

This is a continuation application of PCT Application No. PCT/JP2023/006800, filed on Feb. 24, 2023, which claims priority to Japanese Patent Application No. 2022-040038, filed on Mar. 15, 2022, the entire contents of each of which are incorporated herein by reference.

### BACKGROUND

### 1. Field

This disclosure relates to a semiconductor device.

### 2. Description of Related Art

High-electron-mobility transistors (HEMTs) are now being commercialized. A HEMT uses a group III nitride semiconductor (hereafter, simply referred to as nitride semiconductor), such as gallium nitride (GaN). A HEMT uses two-dimensional electron gas (2DEG) formed near a semiconductor heterojunction interface as a conduction path (channel). A power device using a HEMT has a lower ON resistance and is operable at a higher speed and higher frequency than a typical silicon (Si) power device.

For example, a nitride semiconductor HEMT includes an electron transit layer, which is formed by a gallium nitride (GaN) layer, and an electron supply layer, which is formed by an aluminum gallium nitride (AlGaN) layer. The 2DEG is formed in the electron transit layer near the heterojunction interface of the electron transit layer and the electron supply layer. In a normally-off type HEMT, for example, a semiconductor layer (e.g., p-type GaN layer) containing acceptor impurities is arranged on the electron transit layer and underneath a gate electrode. In this structure, a depletion layer spreading downward from the p-type GaN layer depletes the channel located underneath the p-type GaN layer. This results in the HEMT being normally off. Japanese Laid-Open National Phase Patent Publication No. 2016-529711 discloses such a normally-off type (enhancement mode type) HEMT.

### BRIEF DESCRIPTION OF THE DRAWINGS

FIG. 1 is a schematic cross-sectional view of an exemplary semiconductor device in accordance with a first embodiment.

FIG. 2 is a partially enlarged view of the semiconductor device illustrated in FIG. 1.

FIG. 3 is a partially enlarged view of the semiconductor device illustrated in FIG. 1 and shows gate leakage current paths.

FIG. 4 is a schematic cross-sectional view illustrating a method for manufacturing the semiconductor device of FIG. 1.

FIG. 5 is a schematic cross-sectional view illustrating a step in the manufacturing method following the step of FIG. 4.

FIG. 6 is a schematic cross-sectional view illustrating a step in the manufacturing method following the step of FIG. 5.

FIG. 7 is a schematic cross-sectional view illustrating a step in the manufacturing method following the step of FIG. 6.

FIG. 8 is a schematic cross-sectional view illustrating a step in the manufacturing method following the step of FIG. 7.

FIG. 9 is a schematic cross-sectional view illustrating a step in the manufacturing method following the step of FIG. 8.

FIG. 10 is a schematic cross-sectional view illustrating a step in the manufacturing method following the step of FIG. 9.

FIG. 11 is a schematic cross-sectional view illustrating a step in the manufacturing method following the step of FIG. 10.

FIG. 12 is a schematic cross-sectional view illustrating a step in the manufacturing method following the step of FIG. 11.

FIG. 13 is a schematic cross-sectional view of an exemplary semiconductor device in accordance with a second embodiment.

FIG. 14 is a partially enlarged view of the semiconductor device illustrated in FIG. 13.

FIG. 15 is a partially enlarged view of the semiconductor device illustrated in FIG. 13 and shows gate leakage current paths.

FIG. 16 is a cross-sectional view illustrating a simulation result of the current density of the bulk leakage current flowing through a gate structure (gate including source-side horizontal extension and drain-side horizontal extension) of the second embodiment.

### DETAILED DESCRIPTION

Several embodiments of a semiconductor device in accordance with the present disclosure will now be described with reference to the accompanying drawings. In the drawings, elements are illustrated for simplicity and clarity and have not necessarily been drawn to scale. To aid understanding, hatching lines may not be shown in the cross-sectional drawings. The accompanying drawings illustrate exemplary embodiments in accordance with the present disclosure and are not intended to limit the present disclosure.

The detailed description hereafter provides a comprehensive understanding of exemplary methods, apparatuses, and/or systems in accordance with the present disclosure. This detailed description is illustrative and is not intended to limit embodiments of the present disclosure or the application and use of the embodiments.

### First Embodiment

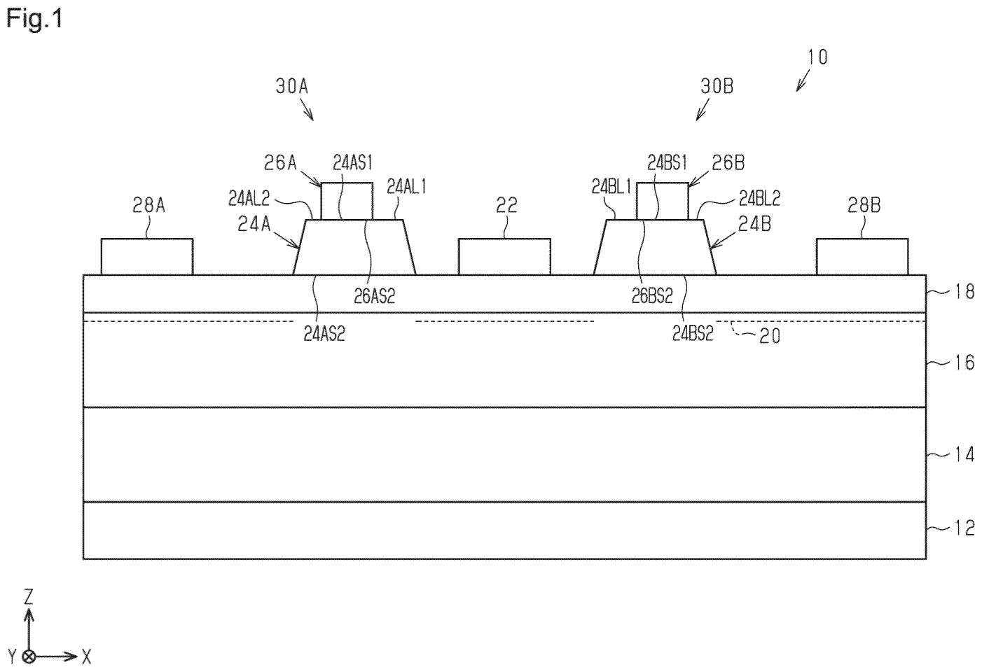

FIG. 1 is a schematic cross-sectional view of an exemplary semiconductor device 10 in accordance with a first embodiment. The overall structure of the semiconductor device 10 will first be described with reference to FIG. 1.

### Overall Structure of Semiconductor Device

The semiconductor device 10 is a HEMT including a group III-V semiconductor. In the first embodiment, a group III nitride semiconductor, which is a group III-V semiconductor, is used. A group III nitride semiconductor refers to a semiconductor using nitrogen as a group V element in a group III-V semiconductor, and representative examples include GaN, aluminum nitride (AlN), and indium nitride (InN). This can generally be expressed as AlₓIn_{y}Ga_{1-x-y}N (0≤x≤1, 0≤y≤1, 0≤x+y≤1). In the first embodiment, the semiconductor device 10 is a HEMT using, for example, GaN.

As shown in FIG. 1, the semiconductor device 10 includes a substrate 12, a buffer layer 14 formed on the substrate 12, an electron transit layer 16 formed on the buffer layer 14, and an electron supply layer 18 formed on the electron transit layer 16.

The semiconductor substrate 12 may be formed from silicon (Si), silicon carbide (SiC), GaN, sapphire, or other substrate materials. For example, the semiconductor substrate 12 is a conductive Si substrate. The substrate 12 may have a thickness of, for example, 200 μm or greater and 1500 μm or less. The drawings (e.g., FIG. 1) show the XYZ axes that are orthogonal to one another. The Z-axis direction is orthogonal to the main surface of the semiconductor substrate 12. Unless otherwise indicated, the term “plan view” as used in this specification will refer to a view of the semiconductor device 10 taken from above in the Z-axis direction.

The buffer layer 14, which is located between the substrate 12 and the electron transit layer 16, may be formed from any material that reduces lattice mismatching between the substrate 12 and the electron transit layer 16. The buffer layer 14 may include, for example, one or more nitride semiconductor layers. For example, the buffer layer 14 may include at least one of an aluminum nitride (AlN) layer, an aluminum gallium nitride (AlGaN) layer, and a graded AlGaN layer having different aluminum (Al) compositions. For example, the buffer layer 14 may include a single AlN layer, a single AlGaN layer, a layer having an AlGaN/GaN superlattice structure, a layer having an AlN/AlGaN superlattice structure, or a layer having an AlN/GaN superlattice structure.

In one example, the buffer layer 14 includes a first buffer layer that is formed on the substrate 12 and a second buffer layer that is formed on the first buffer layer. The first buffer layer is, for example, an AlN layer and may have a thickness of, for example, approximately 200 nm. The second buffer layer includes, for example, multiple AlGaN layers, and each AlGaN layer may have a thickness of, for example, approximately 100 nm. To reduce leakage current in the buffer layer 14, part of the buffer layer 14 may be doped with impurities to be semi-insulating. In this case, the impurities may be carbon (C) or iron (Fe), and the concentration of the impurities may be, for example, 4×10¹⁶ cm⁻³ or greater.

The electron transit layer 16 is a semiconductor layer (corresponding to first semiconductor layer) and may be composed of, for example, a nitride semiconductor. In the first embodiment, the electron transit layer 16 is, for example, a GaN layer. The electron transit layer 16 may have a thickness of, for example, 0.5 μm or greater and 2 μm or less. To inhibit current leakage from the electron transit layer 16, the electron transit layer 16 may be partially doped with impurities so that regions other than the outermost part of the electron transit layer 16 is semi-insulating. In this case, the impurities are, for example, carbon (C). The concentration of the impurities may be, for example, greater than or equal to 1×10¹⁹ cm⁻³ at a peak concentration.

The electron supply layer 18 is a semiconductor layer (corresponding to second semiconductor layer) and may be composed of, for example, a nitride semiconductor. In the first embodiment, the electron supply layer 18 is, for example, an AlGaN layer. The electron supply layer 18 has a larger band gap than the electron transit layer 16. For example, with an AlGaN layer, the band gap becomes larger as the Al composition increases. Thus, the electron supply layer 18, which is an AlGaN layer, has a larger band gap than the electron transit layer 16, which is a GaN layer. For example, the electron supply layer 18 is composed of AlₓGa₁₋ₓN. Here, x is 0.1<x<0.4, more preferably, 0.2<x<0.3, although there is no limitation to such a range. The electron supply layer 18 may have a thickness of, for example, 5 nm or greater and 20 nm or less.

The electron transit layer 16 and the electron supply layer 18 may be composed of nitride semiconductors having different lattice constants. Thus, the nitride semiconductor (e.g., GaN) of the electron transit layer 16 and the nitride semiconductor (e.g., AlGaN) of the electron supply layer 18 form a lattice-mismatched junction. The spontaneous polarization of the electron transit layer 16 and the electron supply layer 18 and the piezoelectric polarization resulting from the stress received by the heterojunction of the electron supply layer 18 cause the energy level of the conduction band of the electron transit layer 16 to be lower than the Fermi level in the proximity of the heterojunction interface between the electron transit layer 16 and the electron supply layer 18. Thus, a two-dimensional electron gas (2DEG) 20 spreads in the electron transit layer 16 at a position proximate to the heterojunction interface of the electron transit layer 16 and the electron supply layer 18 (e.g., distanced by approximately a few nanometers from interface). The concentration of the 2DEG 20 is not particularly limited and may be, for example, approximately 1×10¹³ cm⁻².

The semiconductor device 10 further includes a source electrode 22, a first gate portion 24A, a second gate portion 24B, a first gate electrode 26A, a second gate electrode 26B, a first drain electrode 28A, and a second drain electrode 28B. The source electrode 22, the first gate portion 24A, the second gate portion 24B, the first drain electrode 28A, and the second drain electrode 28B are arranged on the electron supply layer 18.

The source electrode 22 is located between the first gate portion 24A and the second gate portion 24B. In other words, the second gate portion 24B is located at a side of the source electrode 22 opposite the first gate portion 24A. The first gate portion 24A is located between the source electrode 22 and the first drain electrode 28A. In other words, the first drain electrode 28A is located at a side of the first gate portion 24A opposite the source electrode 22. In the same manner, the second gate portion 24B is located between the source electrode 22 and the second drain electrode 28B. In other words, the second drain electrode 28B is located at a side of the second gate portion 24B opposite the source electrode 22.

The source electrode 22 and the first and second drain electrodes 28A and 28B are in ohmic contact with the 2DEG 20 underneath the electron supply layer 18, that is, electrically connected to the 2DEG 20. The source electrode 22 and the first and second drain electrodes 28A and 28B may be formed by, for example, one or more metal layers using at least one of a titanium (Ti) layer, a titanium nitride (TiN) layer, an aluminum (Al) layer, an aluminum silicon copper (AlSiCu) layer, and an aluminum copper (AlCu) layer. In the first embodiment, the source electrode 22 and the first and second drain electrodes 28A and 28B each have, for example, a three-layer structure of a Ti layer, an Al layer, and a Ti layer. This is advantageous in that when the source electrode 22 and the first and second drain electrodes 28A and 28B are formed from the same material, they may be formed in the same process.

Each of the first and second gate portions 24A and 24B is a semiconductor layer (corresponding to third semiconductor layer) containing acceptor impurities and may be composed of, for example, a nitride semiconductor containing acceptor impurities. The first and second gate portions 24A and 24B may be composed of any semiconductor material having a smaller band gap than the electron supply layer 18. In the first embodiment, each of the first and second gate portions 24A and 24B is a GaN layer, or p-type GaN layer, doped with acceptor impurities. The acceptor impurities may include, for example, at least one of zinc (Zn), magnesium (Mg), and carbon (C). In the first embodiment, Mg is used as the acceptor impurities. The maximum concentration of the acceptor impurities is, for example, 7×10¹⁸ cm⁻³ or greater and 1×10²⁰ cm⁻³ or less.

The first and second gate portions 24A and 24B are not particularly limited in thickness and may be determined taking into consideration, for example, the gate breakdown voltage and the like. For example, the first and second gate portions 24A and 24B may each have a thickness of 80 nm or greater and 150 nm or less. Further, the first and second gate portions 24A and 24B are not particularly limited in cross-sectional shape (cross-sectional shape taken along ZX plane in FIG. 1) and may be, for example, rectangular, trapezoidal, or have any other shape. The first and second gate portions 24A and 24B are not particularly limited in length in the X-direction and may be, for example, 0.4 μm or greater and 1.0 μm or less.

The first gate electrode 26A is arranged on part of the first gate portion 24A. In the same manner, the second gate electrode 26B is arranged on part of the second gate portion 24B. The first and second gate electrodes 26A and 26B may each include one or more metal layers, for example, a titanium nitride (TiN) layer. Alternatively, the first and second gate electrodes 26A and 26B may each include a first metal layer (e.g., Ti layer) and a second metal layer (e.g., TiN layer) arranged on the first metal layer. In the first embodiment, the first and second gate electrodes 26A and 26B, which are TiN layers, form Schottky junctions with the first and second gate portions 24A and 24B (p-type GaN layers), respectively. The first and second gate electrodes 26A and 26B each have a thickness of, for example, 50 nm or greater and 300 nm or less.

In the semiconductor device 10 shown in FIG. 1, the electron transit layer 16, the electron supply layer 18, the first gate portion 24A, the first gate electrode 26A, the source electrode 22, and the first drain electrode 28A form a first field-effect transistor (FET) 30A. Further, the electron transit layer 16, the electron supply layer 18, the second gate portion 24B, the second gate electrode 26B, the source electrode 22, and the second drain electrode 28B form a second field-effect transistor (FET) 30B. In the first embodiment, each of the first and second FETs 30A and 30B is a normally-off GaN-HEMT. The semiconductor device 10 in FIG. 1, includes the two FETs 30A and 30B. However, the structure shown in FIG. 1 is actually arranged in a repetitive manner so that the semiconductor device 10 includes a large number of FETs.

In the first FET 30A, for example, the first gate portion 24A, the first gate electrode 26A, the first drain electrode 28A, and the source electrode 22 are arranged so that the gate-drain distance is longer than the gate-source distance while taking into consideration, for example, the drain-source breakdown voltage or the like. The gate-drain distance corresponds to the distance from the first gate portion 24A (end located toward first drain electrode 28A) to the first drain electrode 28A. The gate-source distance corresponds to the distance from the first gate portion 24A (end located toward source electrode 22) to the source electrode 22. For example, in the first FET 30A, the gate-drain distance may be set to be longer than the distance obtained by adding the gate length (length in X-direction) of the first gate electrode 26A to the gate-source distance.

In the same manner, in the second FET 30B, the second gate portion 24B, the second gate electrode 26B, the second drain electrode 28B, and the source electrode 22 are set that the gate-drain distance is longer than the gate-source distance. For example, in the second FET 30B, the gate-drain distance may be set to be longer than the distance obtained by adding the gate length (length of second gate electrode 26B in X-direction) to the gate-source distance.

### Asymmetric Gate Structure of First Field-Effect Transistor.

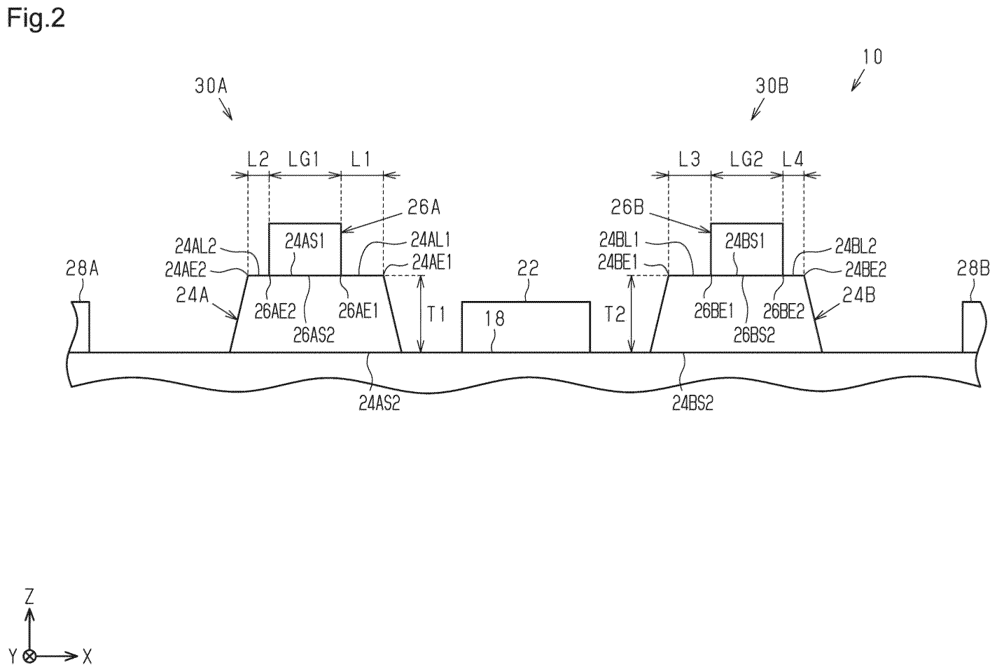

With reference to FIG. 2, the asymmetric gate structure of the first FET 30A will now be described. FIG. 2 is a partially enlarged view of the semiconductor device 10 illustrated in FIG. 1.

As shown in FIG. 2, the first gate portion 24A, which is, for example, trapezoidal in cross section, includes an upper surface 24AS1 and a lower surface 24AS2, which has a greater area than the upper surface 24AS1. The first gate electrode 26A is formed on part of the upper surface 24AS1 of the first gate portion 24A. The first gate electrode 26A, which is, for example, rectangular in cross section, has length LG1 in the direction (X-direction) in which the first drain electrode 28A, the first gate portion 24A, and the source electrode 22 are arranged next to one another. Length LG1 is less than the length of the upper surface 24AS1 of the first gate portion 24A in the X-direction.

Thus, the upper surface 24AS1 of the first gate portion 24A includes a region that is not in contact with a lower surface 26AS2 of the first gate electrode 26A, that is, a region exposed from the lower surface 26AS2 of the first gate electrode 26A and extending outward from the first gate electrode 26A (hereafter, referred to as side-space region). In the example of FIG. 2, the upper surface 24AS1 of the first gate portion 24A includes two side-space regions extending outward in the X-direction from the two side walls of the first gate electrode 26A, namely, a first side-space region 24AL1 and a second side-space region 24AL2. The first side-space region 24AL1, which is the region located toward the source electrode 22, extends in the X-direction over length L1. The second side-space region 24AL2, which is the region located toward the first drain electrode 28A, extends in the X-direction over length L2.

Length L1 and length L2 are determined by the two ends of the upper surface 24AS1 of the first gate portion 24A and the two ends of the lower surface 26AS2 of the first gate electrode 26A. In the example of FIG. 2, the upper surface 24AS1 of the first gate portion 24A includes a first source-side end 24AE1, which is located toward the source electrode 22, and a first drain-side end 24AE2, which is located toward the first drain electrode 28A. The lower surface 26AS2 of the first gate electrode 26A includes a first source-side electrode end 26AE1, which is located toward the source electrode 22, and a first drain-side electrode end 26AE2, which is located toward the first drain electrode 28A.

The first source-side end 24AE1 of the first gate portion 24A is located closer to the source electrode 22 than the first source-side electrode end 26AE1 of the first gate electrode 26A. Accordingly, length L1 of the first side-space region 24AL1 corresponds to the distance between the first source-side end 24AE1 and the first source-side electrode end 26AE1. The first drain-side end 24AE2 of the first gate portion 24A is located closer to the first drain electrode 28A than the first drain-side electrode end 26AE2 of the first gate electrode 26A. Accordingly, length L2 of the second side-space region 24AL2 corresponds to the distance between the first drain-side end 24AE2 and the first drain-side electrode end 26AE2.

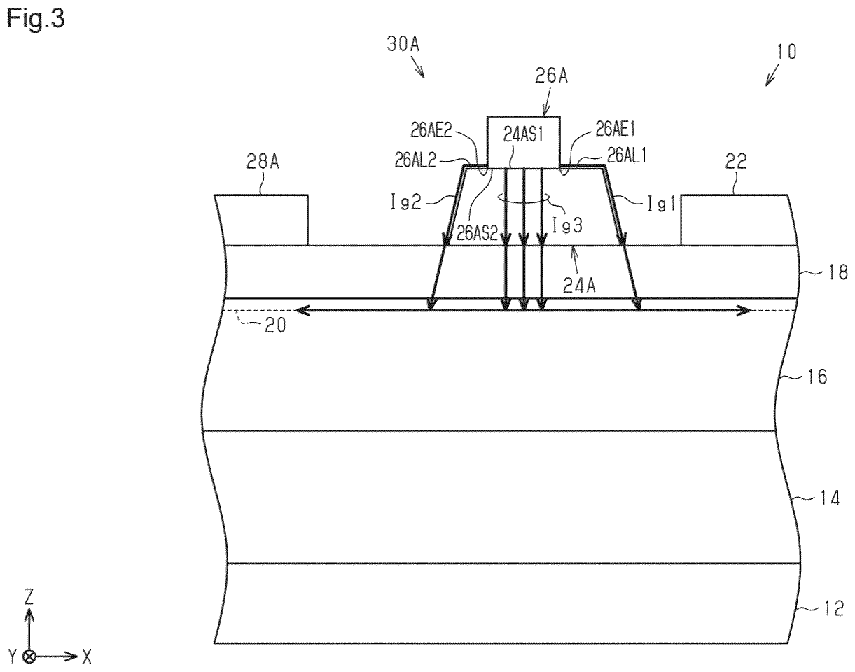

Length L1 of the first side-space region 24AL1 and length L2 of the second side-space region 24AL2 are set to satisfy the relationship of L1>L2, more preferably, the relationship of L1≥2×L2. Thus, as shown in FIG. 2, the first gate electrode 26A arranged on the upper surface 24AS1 of the first gate portion 24A is located toward the first drain electrode 28A from a middle position of the first gate portion 24A in the X-direction. In this manner, the first gate portion 24A and the first gate electrode 26A in the first FET 30A form an asymmetric gate structure in a cross-sectional view taken along a ZX plane. The asymmetric gate structure contributes to inhibit local increases in the current density of the gate leakage current. The relationship of the asymmetric gate structure of the first FET 30A and the gate leakage current will be described later with reference to FIG. 3.

Length L1 of the first side-space region 24AL1 of the first gate portion 24A may be set to be less than or equal to thickness T1 of the first gate portion 24A (distance from upper surface 24AS1 to lower surface 24AS2), although this is not necessarily a limitation. That is, length L1 of the first side-space region 24AL1 and thickness T1 of the first gate portion 24A may be set to satisfy the relationship of L1≤T1.

In the structure in which the first gate portion 24A forms a Schottky junction with the first gate electrode 26A, when positive voltage is applied to the first gate electrode 26A, reverse bias is applied to the Schottky junction thereby spreading a depletion layer in the first gate portion 24A. In this case, when the relationship of L1≤T1 is satisfied, the ratio of the area of the Schottky junction interface (length in X-direction) to the area of the upper surface 24AS1 of the first gate portion 24A (length in X-direction) can be maintained in a satisfactory manner in accordance with thickness T1 of the first gate portion 24A. As a result, the depletion layer that spreads in the vertical direction from the junction interface is also maintained in a satisfactory manner in the horizontal direction (X-direction) with respect to the area of the upper surface 24AS1 of the first gate portion 24A (i.e., spreading of depletion layer is more limited in vertical direction than horizontal direction). This allows the maximum rated gate voltage in the positive direction to be increased.

Length L1 of the first side-space region 24AL1, length L2 of the second side-space region 24AL2, and length LG1 (distance from first source-side electrode end 26AE1 to first drain-side electrode end 26AE2) of the first gate electrode 26A may be set to satisfy the relationship of LG1≥L1+L2, although this is not necessarily a limitation. When this relationship is satisfied, the area (length in X-direction) of the upper surface 24AS1 of the first gate portion 24A contacting the first gate electrode 26A is large. This allows gate signals to be efficiently transmitted from the first gate electrode 26A to the first gate portion 24A. Thus, gate signals can be sufficiently transmitted to the ends of the lower surface 24AS2 of the first gate portion 24A. This improves the subthreshold characteristics. As a result, the drain leakage current (source-drain current leakage) is decreased when the gate voltage is less than or equal to the threshold voltage. Further, the first gate electrode 26A has a large cross-sectional area. This allows the gate resistance to be decreased.

### Asymmetric Gate Structure of Second Field-Effect Transistor

With reference to FIG. 2, the asymmetric gate structure of the second FET 30B will now be described.

In the same manner as the first gate portion 24A described above, the second gate portion 24B, which is, for example, trapezoidal, includes an upper surface 24BS1 and a lower surface 24BS2, which has a greater area than the upper surface 24BS1. The second gate electrode 26B is formed on part of the upper surface 24BS1 of the second gate portion 24B. The second gate electrode 26B, which is, for example, rectangular in cross section, has length LG2 in the direction (X-direction) in which the second drain electrode 28B, the second gate portion 24B, and the source electrode 22 are arranged next to one another. Length LG2 is less than the length of the upper surface 24BS1 of the second gate portion 24B in the X-direction.

Thus, the upper surface 24BS1 of the second gate portion 24B includes a region that is not in contact with the lower surface 26BS2 of the second gate electrode 26B, that is, a region exposed from the lower surface 26BS2 of the second gate electrode 26B and extending outward from the second gate electrode 26B. In the example of FIG. 2, the upper surface 24BS1 of the second gate portion 24B includes two side-space regions extending outward in the X-direction from the two side walls of the second gate electrode 26B, namely, a third side-space region 24BL1 and a fourth side-space region 24BL2. The third side-space region 24BL1, which is the region located toward the source electrode 22, extends in the X-direction over length L3. The fourth side-space region 24BL2, which is the region located toward the second drain electrode 28B, extends in the X-direction over length L4.

Length L3 and length L4 are determined by the two ends of the upper surface 24BS1 of the second gate portion 24B and the two ends of the lower surface 26BS2 of the second gate electrode 26B. In the example of FIG. 2, the upper surface 24BS1 of the second gate portion 24B includes a second source-side end 24BE1, which is located toward the source electrode 22, and a second drain-side end 24BE2, which is located toward the second drain electrode 28B. The lower surface 26BS2 of the second gate electrode 26B includes a second source-side electrode end 26BE1, which is located toward the source electrode 22, and a second drain-side electrode end 26BE2, which is located toward the second drain electrode 28B.

The second source-side end 24BE1 of the second gate portion 24B is located closer to the source electrode 22 than the second source-side electrode end 26BE1 of the second gate electrode 26B. Thus, length L3 of the third side-space region 24BL1 corresponds to the distance between the second source-side end 24BE1 and the second source-side electrode end 26BE1. The second drain-side end 24BE2 of the second gate portion 24B is located closer to the second drain electrode 28B than the second drain-side electrode end 26BE2 of the second gate electrode 26B. Thus, length L4 of the fourth side-space region 24BL2 corresponds to the distance between the second drain-side end 24BE2 and the second drain-side electrode end 26BE2.

Length L3 of the third side-space region 24BL1 and length L4 of the fourth side-space region 24BL2 are set to satisfy the relationship of L3>L4, more preferably, the relationship of L3≥2×L4. Thus, as shown in FIG. 2, the second gate electrode 26B arranged on the upper surface 24BS1 of the second gate portion 24B is located toward the second drain electrode 28B from a middle position of the second gate portion 24B in the X-direction. In this manner, the second gate portion 24B and the second gate electrode 26B in the second FET 30B form an asymmetric gate structure in a cross-sectional view taken along a ZX plane. The asymmetric gate structure contributes to inhibit local increases in the current density of the gate leakage current. The relationship of the asymmetric gate structure of the second FET 30B and the gate leakage current will be described later with reference to FIG. 3.

In the same manner as the first gate portion 24A, length L3 of the third side-space region 24BL1 of the second gate portion 24B may be set to be less than or equal to thickness T2 of the second gate portion 24B (distance from upper surface 24BS1 to lower surface 24BS2), although this is not necessarily a limitation. That is, length L3 of the third side-space region 24BL1 and thickness T2 of the second gate portion 24B may be set to satisfy the relationship of L3≤T2. When this relationship is satisfied, a depletion layer spreading in the vertical direction from the Schottky junction interface of the second gate electrode 26B and the second gate portion 24B can be maintained in a satisfactory manner in the horizontal direction (X-direction) with respect to the area of the upper surface 24BS1 of the second gate portion 24B. This allows the maximum rated gate voltage in the positive direction to be increased.

Further, in the same manner as the first gate portion 24A, length L3 of the third side-space region 24BL1, length L4 of the fourth side-space region 24BL2, and length LG2 (distance from second source-side electrode end 26BE1 to second drain-side electrode end 26BE2) of the second gate electrode 26B may be set to satisfy the relationship of LG2≥L3+L4, although this is not necessarily a limitation. When this relationship is satisfied, the area (length in X-direction) of the upper surface 24BS1 of the second gate portion 24B contacting the second gate electrode 26B is large. This allows gate signals to be efficiently transmitted from the second gate electrode 26B to the second gate portion 24B. As a result, the subthreshold characteristics is improved, and the drain leakage current when the gate voltage is less than or equal to the threshold voltage is decreased. Further, the second gate electrode 26B has a large cross-sectional area. This allows the gate resistance to be decreased.

### Relationship of First Field-Effect Transistor and Second Field-Effect Transistor

With reference to FIG. 2, the relationship of the first FET 30A and the second FET 30B will now be described.

As described above, the first FET 30A has an asymmetric gate structure, and the second FET 30B has an asymmetric gate structure. In addition, the first FET 30A and the second FET 30B are symmetric at left and right sides of a substrate orthogonal axis that extends in the Z-direction at the center of the source electrode 22 in the X-direction, although this is not necessarily a limitation.

For example, in the first embodiment, the first FET 30A corresponds to the part of the semiconductor device 10 from the first drain electrode 28A to the source electrode 22 in the X-direction, and has an asymmetric gate structure formed by the first gate portion 24A and the first gate electrode 26A. Further, the second FET 30B corresponds to the part of the semiconductor device 10 from the second drain electrode 28B to the source electrode 22 in the X-direction, and has an asymmetric gate structure formed by the second gate portion 24B and the second gate electrode 26B. With regard to some or all features of the first FET 30A and the second FET 30B related to structure, dimension, and arrangement (position of each member), the first and second FETs 30A and 30B are symmetric at left and right sides of the substrate orthogonal axis extending through the center of the source electrode 22.

For example, lengths L1 to L4 of the first to fourth side-space regions 24AL1, 24AL2, 24BL1, and 24BL2 may be set to satisfy L1>L2 (or L1≥2×L2) and L3>L4 (or L3≥2×L4), while also satisfying L1=L3 and L2=L4. In addition, the first and second FETs 30A and 30B may be symmetric with respect to features other than those described above.

### Relationship of Asymmetric Gate Structure and Gate Leakage Current

With reference to FIG. 3, the relationship of the asymmetric gate structure of the FETs 30A and 30B and the gate leakage current flowing through the gate portions 24A and 24B will now be described.

FIG. 3 is a partially enlarged view of the semiconductor device 10 illustrated in FIG. 1 and shows gate leakage current paths in the first FET 30A. Although the description will focus on the first FET 30A, the same applies to the second FET 30B.

In the description hereafter, an asymmetric gate structure will be compared with a symmetric gate structure. As described above, an asymmetric gate structure is a structure in which the first gate electrode 26A is arranged on the first gate portion 24A so as to satisfy the relationship of L1>L2 (refer to FIG. 2). In contrast, a symmetric gate structure is a structure in which a gate electrode is arranged on the first gate portion 24A so as to satisfy the relationship of L1=L2 (e.g., structure of Patent Literature 1). More specifically, in a symmetric gate structure, the gate structure is arranged at a central position in the X-direction on the upper surface 24AS1 of the first gate portion 24A. To aid understanding, structures and elements that are the same or are in correspondence in the asymmetric gate structure and the symmetric gate structures will be described using the same reference numerals.

In the first FET 30A, the first gate portion 24A is arranged underneath the first gate electrode 26A. When positive voltage is applied to the first gate electrode 26A, gate leakage current flows through the first gate portion 24A from the lower surface 26AS2 of the first gate electrode 26A toward the 2DEG 20. The gate leakage current is divided into first to third leakage currents Ig1, Ig2, and Ig3 that flow along the three paths described below.

The first leakage current Ig1 is current that flows from the first source-side electrode end 26AE1 of the first gate electrode 26A along the first side-space region AL1 of the first gate portion 24A and the side surface of the first gate portion 24A (side surface located toward source electrode 22) and then toward the 2DEG 20.

The second leakage current Ig2 is current that flows from the first drain-side electrode end 26AE2 of the first gate electrode 26A along the second side-space region AL2 of the first gate portion 24A and the side surface of the first gate portion 24A (side surface located toward first drain electrode 28A) and then toward the 2DEG 20.

The third leakage current Ig3 flows from the lower surface 26AS2 of the first gate electrode 26A through the inside of the first gate portion 24A and then toward the 2DEG 20.

When voltage greater than or equal to the threshold value is applied to the first gate electrode 26A thereby generating the 2DEG 20, the second leakage current Ig2 is divided into current that flows through the 2DEG 20 toward the source electrode 22 and current that flows through the 2DEG 20 toward the first drain electrode 28A. In contrast, most of the first and third leakage currents Ig1 and Ig3 flows through the 2DEG 20 toward the source electrode 22.

The first and second leakage currents Ig1 and Ig2 are surface leakage currents. In contrast, the third leakage current Ig3 is bulk leakage current. In a structure in which, for example, the first gate electrode 26A forms a Schottky junction with the first gate portion 24A, the surface leakage current is often about the same or greater than the bulk leakage current although this depends on the material of the first gate portion 24A, the material of the protective film covering the first gate portion 24A, and other conditions.

In addition, as described above, in the first FET 30A, the gate-drain distance is greater than the gate-source distance (e.g., distance obtained by adding gate length of first gate electrode 26A to gate-source distance). Thus, the path of the first leakage current Ig1 flowing along the first side-space region 24AL1 and the like to the source electrode 22 is shorter than the path of the second leakage current Ig2 flowing along the second side-space region 24AL2 and the like toward the source electrode 22 (and first drain electrode 28A). In a symmetric gate structure, such a difference in path distance will result in the first leakage current Ig1 being prominently greater than the second leakage current Ig2.

In particular, the first source-side electrode end 26AE1 of the first gate electrode 26A is not only the origin of the first leakage current Ig1 but also the origin of part of the third leakage current Ig3. Accordingly, the section of the first gate portion 24A located underneath the first source-side electrode end 26AE1 is where more gate leakage current concentrates than other locations. Thus, in a symmetric gate structure in which the first leakage current Ig1 becomes prominently greater than the second leakage current Ig2, the current density is particularly high at the section of the first gate portion 24A located underneath the gate electrode end that is located toward the source electrode 22.

In such a manner, at a section where the current density of the gate leakage current is locally high, impact ionization generates electron-hole pairs. This acts as a positive feedback that further increases the gate leakage current originating from the locally high section. The increased gate leakage current causes crystal defects in the first gate portion 24A. As a result, at a section where the current density is initially high locally, crystal defects caused by gate leakage current increase over time. This leads to crystal breakdown of the first gate portion 24A. Thus, in a symmetric gate structure in which an electric field applied to the first gate portion 24A is less than the insulation breakdown electric field, the existence of a location where the current density is initially high locally may cause crystal breakdown at the first gate portion 24A. Such crystal breakdown will decrease the maximum rated gate voltage in the positive direction.

In this respect, the first gate electrode 26A is arranged on the upper surface 24AS1 of the first gate portion 24A so as to form an asymmetric gate structure satisfying the relationship of L1>L2 (refer to FIG. 2). In this structure, length L1 of the first side-space region 24AL1 is greater than length L2 of the second side-space region 24AL2. This decreases the first leakage current Ig1. More specifically, with the asymmetric gate structure that satisfies the relationship of L1>L2, the path of the first leakage current Ig1 is longer than that of the symmetric gate structure. This reduces the difference in path distance, which is described above, and decreases the first leakage current Ig1. As a result, the current density is decreased at the section of the first gate portion 24A located underneath the first source-side electrode end 26AE1. This increases the maximum rated gate voltage in the positive direction at the first FET 30A.

The relationship of L1>L2 results in the path of the second leakage current Ig2 being shorter than that of the symmetric gate structure. In any case, the path of the second leakage current Ig2 is relatively long. Thus, the second leakage current Ig2 is relatively small. Accordingly, even though the increase in length L1 decreases length L2, the increase in the second leakage current Ig2 is subtle.

The inventors have found that as length L1 of the first side-space region 24AL1 becomes greater than length L2 of the second side-space region 24AL2, the first leakage current Ig1 decreases exponentially. From this viewpoint, it is more preferable that lengths L1 and L2 be set to satisfy the relationship of L1≥2×L2. When this relationship is satisfied, the path of the first leakage current Ig1 flowing along the first side-space region 24AL1 and the like becomes further longer. This relatively increases the third leakage current Ig3 as compared with the condition of L1>L2, and further decreases the first leakage current Ig1. As a result, the current density of the gate leakage current is further decreased at the section of the first gate portion 24A located underneath the first source-side electrode end 26AE1.

The description hereabove is also applied to the second FET 30B in the same manner. In the second FET 30B, the second gate electrode 26B is arranged on the upper surface 24BS1 of the second gate portion 24B so as to form an asymmetric gate structure satisfying the relationship of L3>L4 (refer to FIG. 2). This decreases the current density at the section of the second gate portion 24B located underneath the second source-side electrode end 26BE1 of the second gate electrode 26B. Thus, the maximum rated gate voltage in the positive voltage is increased at the second FET 30B. Further, in this case, when lengths L3 and L4 satisfy the relationship of L3≥2×L4, the current density is further decreased at the section of the second gate portion 24B located underneath the second source-side electrode end 26BE1.

### Method for Manufacturing Semiconductor Device

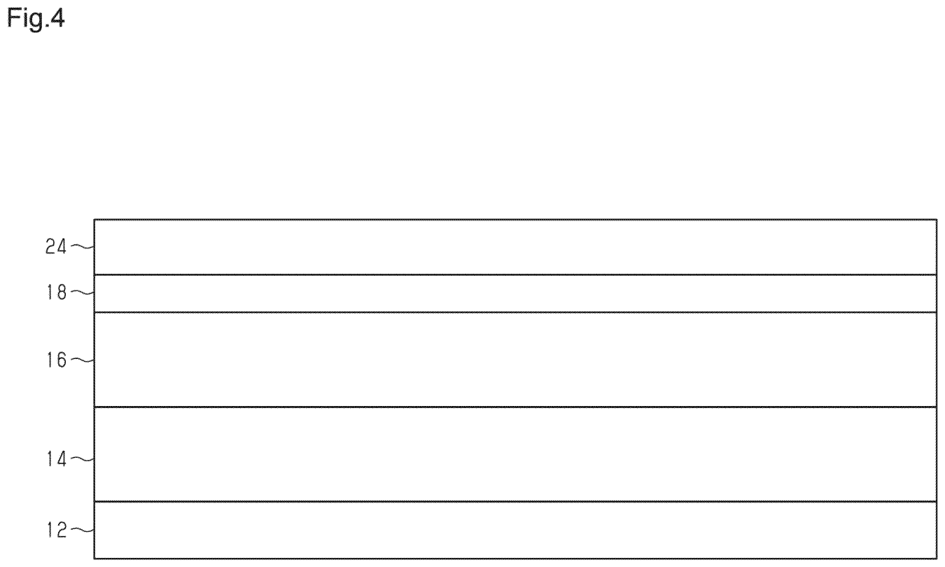

With reference to FIGS. 4 to 12, a method for manufacturing the semiconductor device 10 will now be described. FIGS. 4 to 12 are schematic cross-sectional views illustrating exemplary manufacturing steps of the semiconductor device 10. To aid understanding, members corresponding to the final elements of the semiconductor device 10 are denoted by the reference characters used in FIG. 1.

As shown in FIG. 4, for example, the buffer layer 14, the first semiconductor layer corresponding to the electron transit layer 16, the second semiconductor layer corresponding to the electron supply layer 18, and a third semiconductor layer corresponding to a gate layer 24 are sequentially grown epitaxially on the substrate 12, which is a conductive Si substrate. The epitaxial growth process may be, for example, a Metal Organic Chemical Vapor Deposition (MOCVD) process.

The gate layer 24 is a layer for forming the first and second gate portions 24A and 24B shown in FIG. 1. The buffer layer 14, the electron transit layer 16, the electron supply layer 18, and the gate layer 24 may each be formed from any material and with any thickness in accordance with the corresponding structures described with reference to FIG. 1. In the first embodiment, the electron transit layer 16 is a GaN layer, the electron supply layer 18 is an AlGaN layer, and the gate layer 24 is a p-type GaN layer doped with the acceptor impurities of Mg. Further, the buffer layer 14 has a thickness of, for example, 1.5 μm, the electron transit layer 16 has a thickness of, for example, 1 μm, the electron supply layer 18 has a thickness of, for example, 20 nm, and the gate layer 24 has a thickness of, for example, 100 nm.

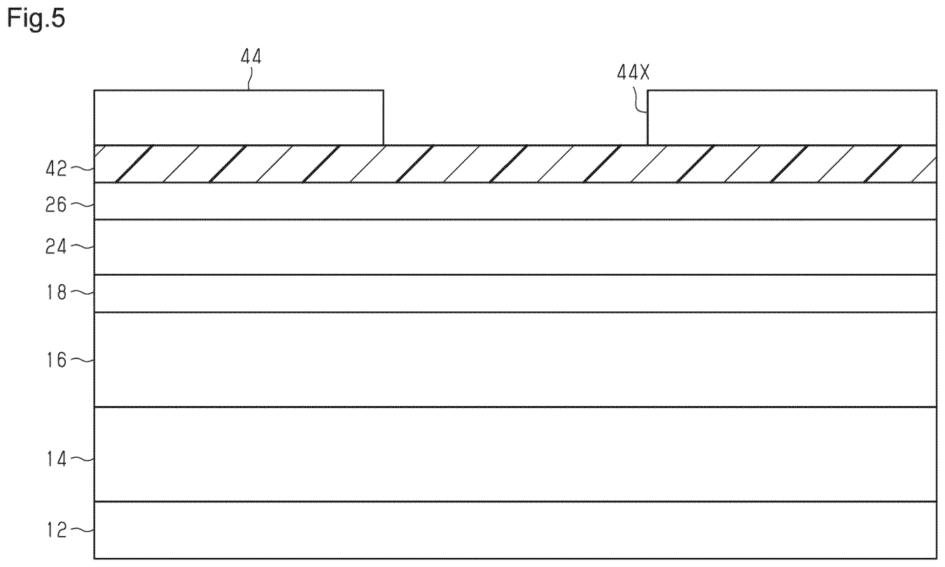

As shown in FIG. 5, a gate electrode layer 26 is formed on the gate layer 24 through, for example, a sputtering process. The gate electrode layer 26 is a layer for forming the first and second gate electrodes 26A and 26B shown in FIG. 1. The gate electrode layer 26 may be formed from any material and with any thickness in accordance with the structures of the first and second gate electrodes 26A and 26B described with reference to FIG. 1. In the first embodiment, the gate electrode layer 26 is a TiN layer having a thickness of, for example, 200 nm.

A first protective layer 42 is formed on the gate electrode layer 26 through, for example, a Plasma-Enhanced Chemical Vapor Deposition (PECVD) process. In the first embodiment, the first protective layer 42 is, for example, a SiN layer and has a thickness of, for example, 200 nm. The first protective layer 42 is not particularly limited in material and thickness.

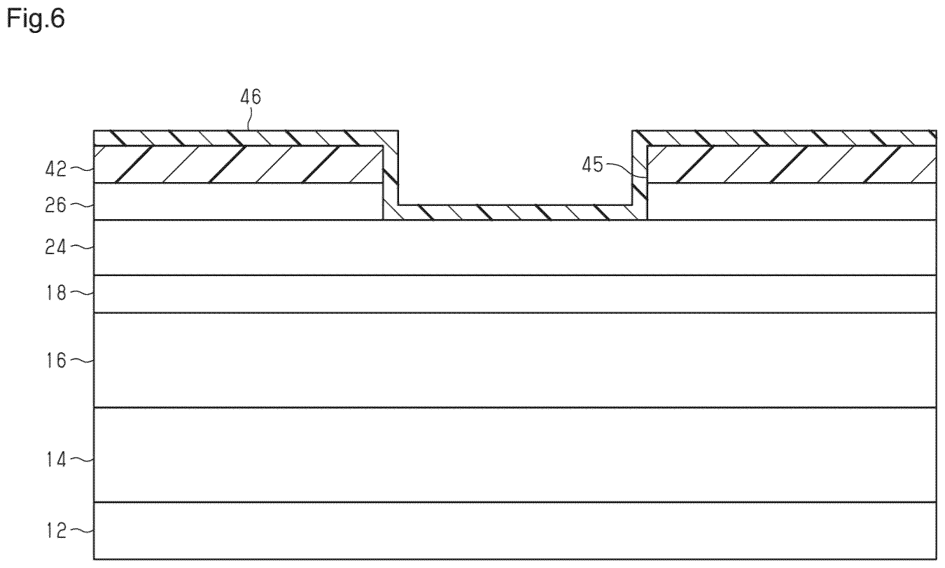

A mask 44 including an opening 44X is formed on the first protective layer 42. Then, etching (e.g., dry etching) is performed with the mask 44 to remove the first protective layer 42 and the gate electrode layer 26 at a position corresponding to the opening 44X. The etching forms a through hole 45 (refer to FIG. 6) extending through the first protective layer 42 and the gate electrode layer 26 at the position corresponding to the opening 44X. This exposes the surface of the gate layer 24 through the through hole 45. The mask 44 is then removed.

As shown in FIG. 6, a second protective layer 46 entirely covering the surfaces of the gate layer 24, the gate electrode layer 26, and the first protective layer 42 is formed through, for example, a PECVD process. In the first embodiment, the second protective layer 46 is, for example, a SiN layer and has a thickness of, for example, 80 nm. The second protective layer 46 is not particularly limited in material and thickness.

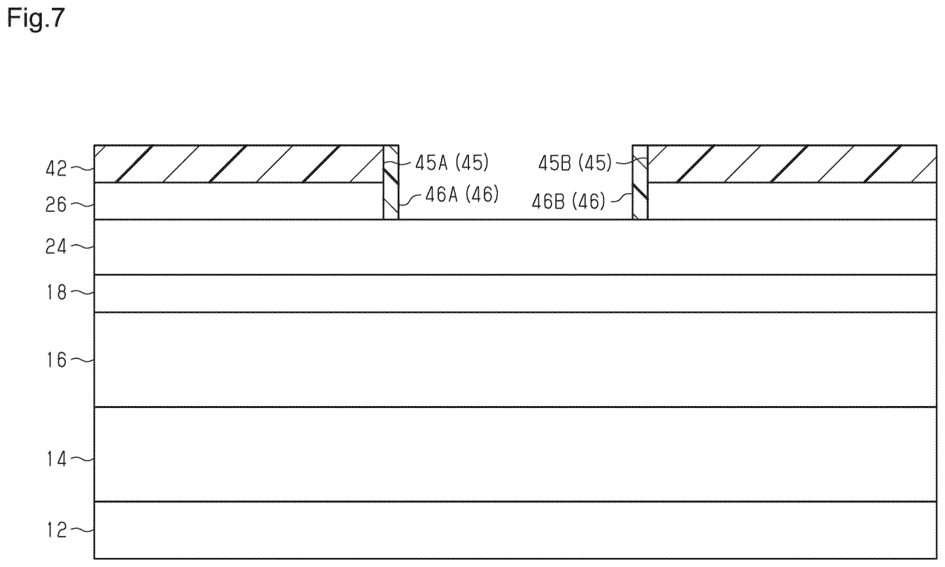

As shown in FIG. 7, the second protective layer 46 undergoes etch backing until the surface of the second protective layer 46 is exposed. The etch backing forms a first side wall 46A and a second side wall 46B respectively covering a first side surface 45A and a second side surface 45B of the through hole 45. Each of the first and second side walls 46A and 46B is a part of the second protective layer 46 remaining subsequent to the etch backing. When the thickness of the second protective layer 46 is 80 nm, the first side wall 46A and the second side wall 46B each have a thickness of, for example, approximately, 40 nm.

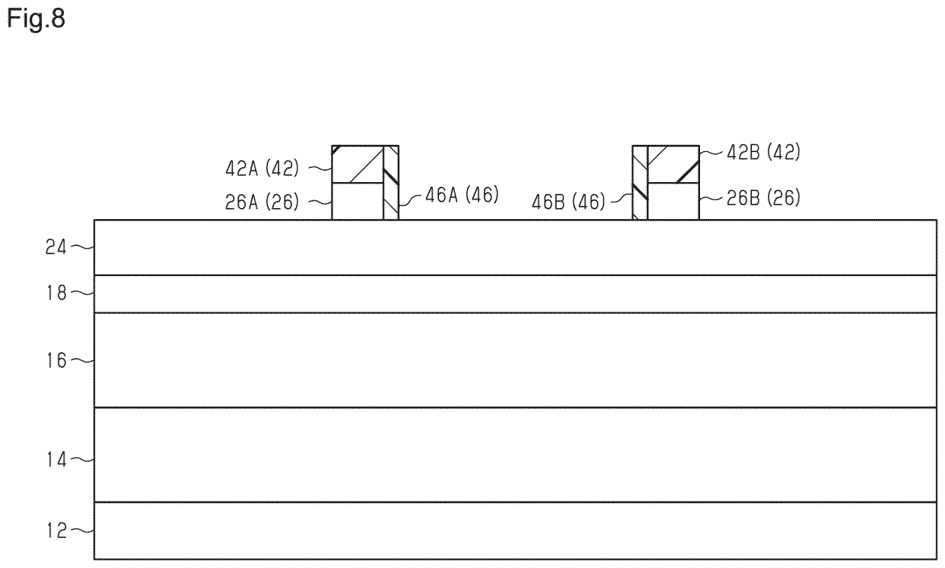

As shown in FIG. 8, the first protective layer 42 and the gate electrode layer 26 are selectively etched to form the first gate electrode 26A and the second gate electrode 26B. For example, a mask having openings at positions corresponding to where the first and second gate electrodes 26A and 26B are formed is applied to the structure of FIG. 7. Then, etching (e.g., dry etching) is performed with the mask on the first protective layer 42 and the gate electrode layer 26 to form the first gate electrode 26A and the second gate electrode 26B. In the first embodiment, the first and second gate electrodes 26A and 26B each have a length (gate length) of, for example, 500 nm. In any case, there is no limitation to the gate length. The etching results in the first protective layer 42 forming a first upper wall 42A covering the first gate electrode 26A and a second upper wall 42B covering the second gate electrode 26B.

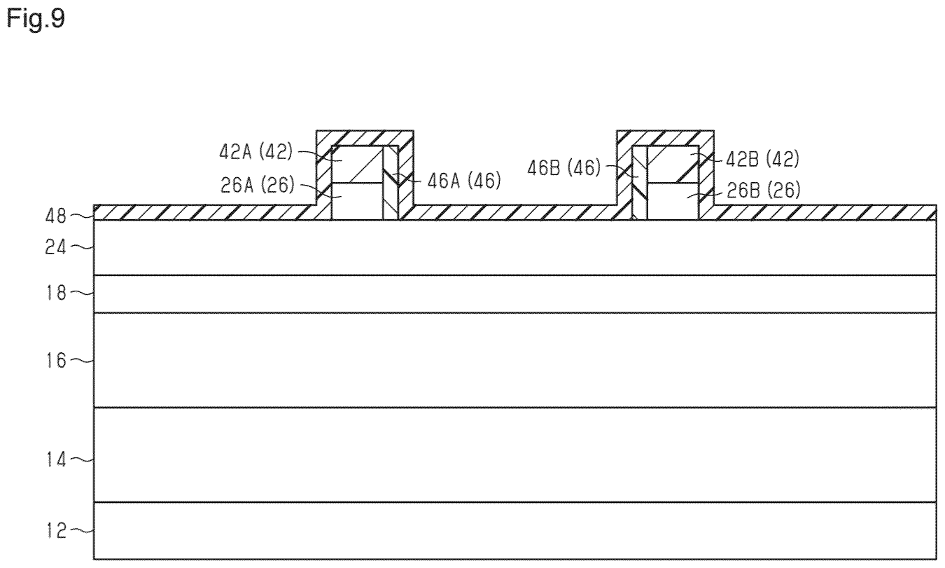

As shown in FIG. 9, a third protective layer 48 entirely covering the surfaces of the gate layer 24, the first gate electrode 26A, the first upper wall 42A, the first side wall 46A, the second gate electrode 26B, the second upper wall 42B, and the second side wall 46B is formed through, for example, a PECVD process. In the first embodiment, the third protective layer 48 is, for example, a SiN layer and has a thickness of, for example, 80 nm. The third protective layer 48 is not particularly limited in material and thickness.

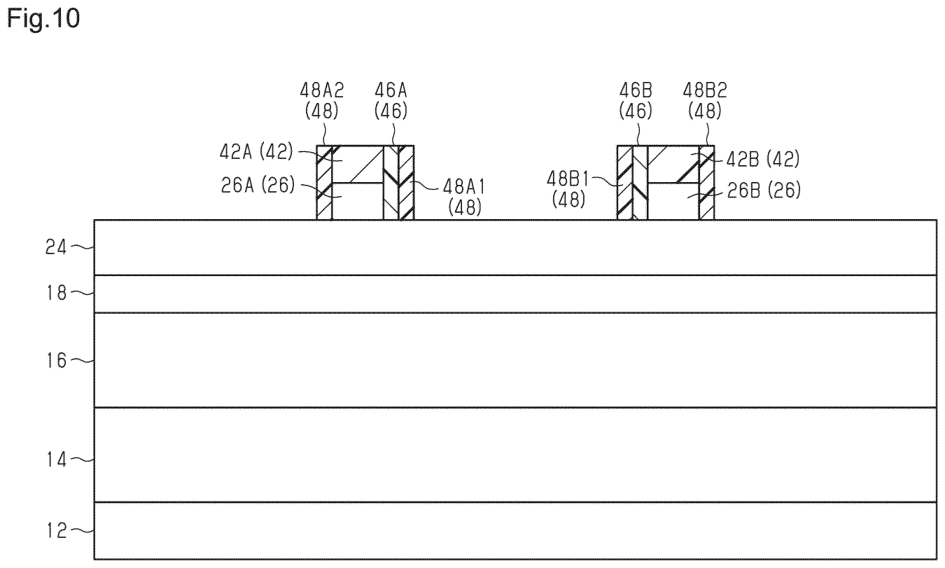

As shown in FIG. 10, the third protective layer 48 undergoes etch backing until the surface of the second gate layer 24 is exposed. The etch backing forms a third side wall 48A1, which covers the first side wall 46A, and a fourth side wall 48B1, which covers the second side wall 46B. A fifth side wall 48A2, which covers the first gate electrode 26A (and first upper wall 42A), and a sixth side wall 48B2, which covers the second gate electrode 26B (and second upper wall 42B), are also formed. Each of the third side wall 48A1, the fourth side wall 48B1, the fifth side wall 48A2, and the sixth side wall 48B2 is a part of the third protective layer 48 remaining subsequent to the etch backing. When the thickness of the third protective layer 48 is 80 nm, the third side wall 48A1, the fourth side wall 48B1, the fifth side wall 48A2, and the sixth side wall 48B2 each have a thickness of, for example, approximately 40 nm.

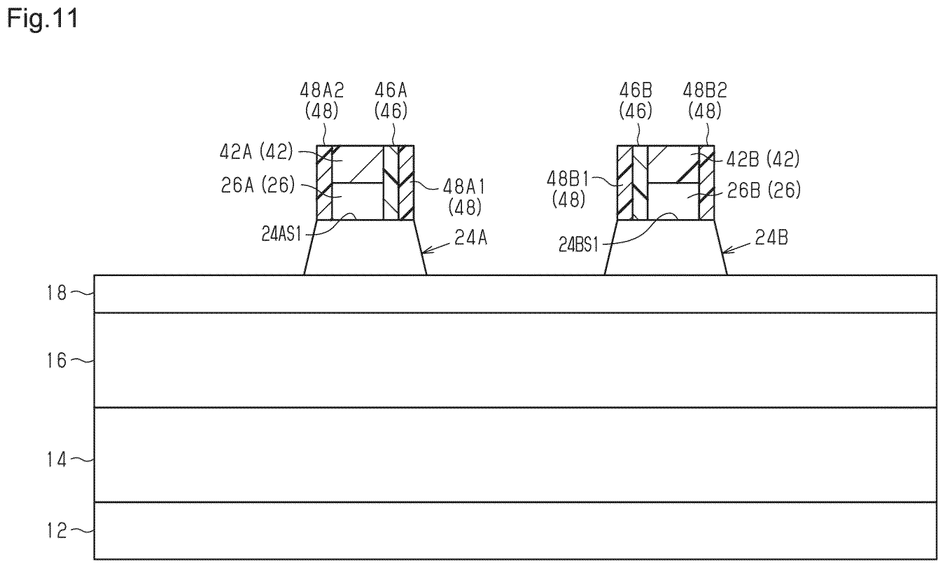

As shown in FIG. 11, the first upper wall 42A, the second upper wall 42B, the first side wall 46A, the second side wall 46B, the third side wall 48A1, the fourth side wall 48B1, the fifth side wall 48A2, and the sixth side wall 48B2 are used as a mask to etch (e.g., dry etch) the gate layer 24 and form the first gate portion 24A and the second gate portion 24B. For example, in this step, the dry etching conditions are selected to minimize damages to the gate layer 24. This forms each of the first and second gate portions 24A and 24B with the trapezoidal cross-sectional shape shown in FIG. 11.

The length of the upper surface 24AS1 of the first gate portion 24A is approximately 620 nm and substantially equal to the sum of the gate length of the first gate electrode 26A, the thickness of the first side wall 46A, the thickness of the third side wall 48A1, and the thickness of the fifth side wall 48A2. In the same manner, the length of the upper surface 24BS1 of the second gate portion 24B is approximately 620 nm and substantially equal to the sum of the gate length of the second gate electrode 26B, the thickness of the second side wall 46B, the thickness of the fourth side wall 48B1, and the thickness of the sixth side wall 48B2.

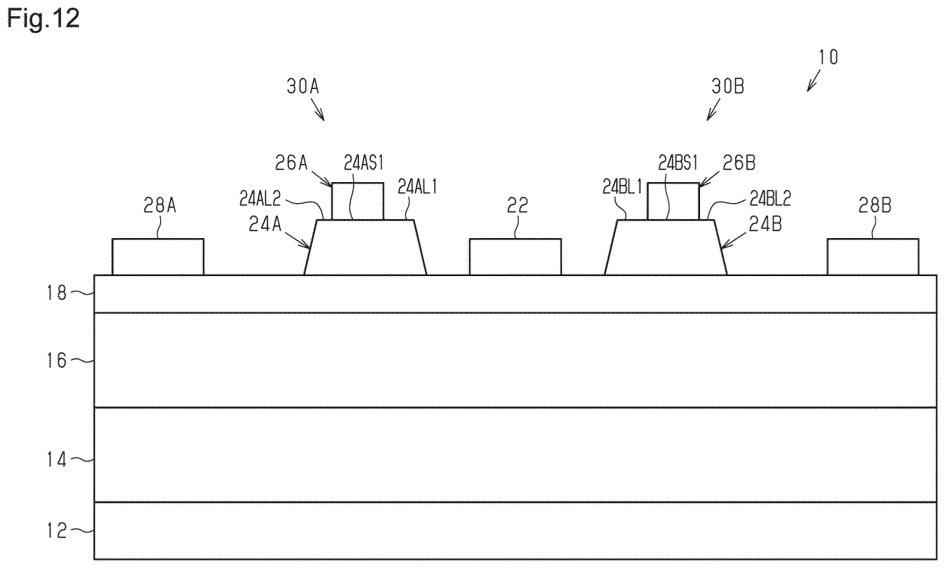

As shown in FIG. 12, the first upper wall 42A, the second upper wall 42B, the first side wall 46A, the second side wall 46B, the third side wall 48A1, the fourth side wall 48B1, the fifth side wall 48A2, and the sixth side wall 48B2 are removed. As a result, the first side-space region 24AL1 and the second side-space region 24AL2 are formed in the upper surface 24AS1 of the first gate portion 24A. Further, the third side-space region 24BL1 and the fourth side-space region 24BL2 are formed in the upper surface 24BS1 of the second gate portion 24B.

Length L1 of the first side-space region 24AL1 (refer to FIG. 2), which is substantially equal to the sum of the thickness of the first side wall 46A and the thickness of the third side wall 48A1, is approximately 80 nm. Further, length L2 of the second side-space region 24AL2 (refer to FIG. 2), which is substantially equal to thickness of the fifth side wall 48A2, is approximately 40 nm. Thus, in this example, the relationship of L1≥2×L2 is satisfied.

In the same manner, length L3 of the third side-space region 24BL1 (refer to FIG. 2), which is substantially equal to the thickness of the second side wall 46B and the thickness of the fourth side wall 48B1, is approximately 80 nm. Further, length L4 of the fourth side-space region 24BL2 (refer to FIG. 2), which is substantially equal to the sixth side wall 48B2, is approximately 40 nm. Thus, in this example, the relationship of L3≥2×L4 is satisfied.

As shown in FIG. 12, the source electrode 22, the first drain electrode 28A, and the second drain electrode 28B are simultaneously formed. The source electrode 22, the first drain electrode 28A, and the second drain electrode 28B may each be formed from any material and with any thickness in accordance with the corresponding structures described with reference to FIG. 1. In the first embodiment, the source electrode 22, the first drain electrode 28A, and the second drain electrode 28B each have a three-layer structure including a Ti layer, an Al layer, and a Ti layer. Subsequently, a heat treatment process (annealing process) is performed at, for example, approximately 600 degrees to complete the semiconductor device 10 having the structure of FIG. 1.

### Operation of Semiconductor Device

The operation of the semiconductor device 10 will now be described.

A normally-off type HEMT includes a p-type gate layer, for example, a semiconductor layer such as a p-type GaN layer containing acceptor impurities, underneath the gate electrode, and has a relatively low maximum rated gate voltage in the positive direction, which is an absolute maximum rating. For example, in several HEMT products, the maximum rated gate voltage in the positive direction is approximately +6 V, while the gate driving voltage is approximately +5 V. In such a case, there is a difference of only approximately 1 V.

In a HEMT including a p-type gate layer underneath the gate electrode, when positive voltage is applied to the gate electrode, gate leakage current may flow from the lower end of the gate electrode through the p-type gate layer and toward the 2DEG. Such gate leakage current decreases the maximum rated gate voltage in the positive direction. For example, if the current density of the gate leakage current increases locally in certain sections of the p-type gate layer, crystal defects may occur in the p-type gate layer at such areas. Such crystal defects will further increase the gate leakage current thereby increasing crystal defects over time and consequently causing crystal breakdown. This decreases the maximum rated gate voltage in the positive direction. Accordingly, there is still room for improvement with regard to inhibiting local increases in the current density of the gate leakage current in order to increase the maximum rated gate voltage in the positive direction.

As shown in FIG. 1, the semiconductor device 10 includes the first and second gate portions 24A and 24B, which are formed by semiconductor layers containing acceptor impurities. The first and second gate electrodes 26A and 26B are respectively arranged on parts of the first and second gate portions 24A and 24B. The upper surface 24AS1 of the first gate portion 24A includes the first side-space region 24AL1, which is located toward the source electrode 22 and extends over length L1, and the second side-space region 24AL2, which is located toward the first drain electrode 28A and extends over length L2. The upper surface 24BS1 of the second gate portion 24B includes the third side-space region 24BL1, which is located toward the source electrode 22 and extends over length L3, and the fourth side-space region 24BL2, which is located toward the second drain electrode 28B and extends over length L4.

As shown in FIG. 2, lengths L1 and L2 satisfy the relationship of L1>L2. Thus, the first gate portion 24A and the first gate electrode 26A form an asymmetric gate structure. Further, lengths L3 and L4 satisfy the relationship of L3>L4. Thus, the second gate portion 24B and the second gate electrode 26B form an asymmetric gate structure.

The operation of the asymmetric gate structure formed by the first gate portion 24A and the first gate electrode 26A will be described below. The same applies to the asymmetric gate structure formed by the second gate portion 24B and the second gate electrode 26B.

As shown in FIG. 3, when positive voltage is applied to the first gate electrode 26A, gate leakage current may flow through the first gate portion 24A from the lower surface 26AS2 of the first gate electrode 26A toward the 2DEG 20. The gate leakage current is divided into the first leakage current Ig1, which flows along the first side-space region AL1 and the like, the second leakage current Ig2, which flows along the second side-space region AL2 and the like, and the third leakage current Ig3, which flows through the inside of the first gate portion 24A.

The first source-side electrode end 26AE1 of the first gate electrode 26A is not only the origin of the first leakage current Ig1 but also the origin of part of the third leakage current Ig3. Thus, the section of the first gate portion 24A located underneath the first source-side electrode end 26AE1 is where more gate leakage current concentrates than other locations.

In this respect, the first gate electrode 26A is arranged on the upper surface 24AS1 of the first gate portion 24A so as to satisfy the relationship of L1>L2 (refer to FIG. 2). In this structure, length L1 of the first side-space region 24AL1 is greater than length L2 of the second side-space region 24AL2. This decreases the first leakage current Ig1. More specifically, with the asymmetric gate structure satisfying the relationship of L1>L2, the path of the first leakage current Ig1 is longer than that of a symmetric gate structure. This decreases the first leakage current Ig1. As a result, the current density is decreased at the section of the first gate portion 24A located underneath the first source-side electrode end 26AE1. This increases the maximum rated gate voltage in the positive direction.

The semiconductor device 10 of the first embodiment has the advantages described below.

(1-1) In the first gate portion 24A, length L1 of the first side-space region 24AL1 and length L2 of the second side-space region 24AL2 satisfy the relationship of L1>L2. Further, in the second gate portion 24B, length L1 of the third side-space region 24BL1 and the length of the fourth side-space region 24BL2 satisfy the relationship of L3>L4.

With this structure, the path of the first leakage current Ig1 flowing along the first side-space region 24AL1 and the like of the first gate portion 24A is lengthened. This decreases the current density of the gate leakage current at the section of the first gate portion 24A located underneath the first source-side electrode end 26AE1. This inhibits local increases in the current density. As a result, the asymmetric gate structure formed by combining the first gate portion 24A and the first gate electrode 26A increases the maximum rated gate voltage in the positive direction.

Further, in the same manner as the first gate portion 24A, the path of the first leakage current Ig1 along the third side-space region 24BL1 of the second gate portion 24B is lengthened. This decreases the current density of the gate leakage current at the section of the second gate portion 24B located underneath the second source-side electrode end 26BE1. This inhibits local increases in the current density. As a result, the asymmetric gate structure formed by combining the second gate portion 24B and the second gate electrode 26B increases the maximum rated gate voltage in the positive direction.

(1-2) Length L1 and length L2 satisfy the relationship of L1≥2×L2, and length L3 and length L4 satisfy the relationship of L3≥2×L4. With this structure, the path of the first leakage current Ig1 is further lengthened in each of the first and second gate portions 24A and 24B. This relatively increases the third leakage current Ig3 and further decreases the first leakage current Ig1. As a result, local increase in the current density is further inhibited, and the maximum rated gate voltage in the positive direction is increased.

(1-3) Length L1 of the first side-space region 24AL1 and thickness T1 of the first gate portion 24A satisfy the relationship of L1≤T1. Further, length L3 of the third side-space region 24BL1 and thickness T2 of the second gate portion 24B satisfy the relationship of L3≤T2.

In the structure in which the first gate portion 24A forms a Schottky junction with the first gate electrode 26A, when positive voltage is applied to the first gate electrode 26A, reverse bias is applied to the Schottky junction thereby spreading the depletion layer in the first gate portion 24A. In this case, when the relationship of L1≤T1 is satisfied in the first gate portion 24A, the ratio of the area of the Schottky junction interface to the area of the upper surface 24AS1 of the first gate portion 24A can be maintained in a satisfactory manner in accordance with thickness T1 of the first gate portion 24A. As a result, the depletion layer that spreads in the vertical direction from the junction interface is also maintained in a satisfactory manner in the horizontal direction (X-direction) with respect to the area of the upper surface 24AS1 of the first gate portion 24A. This increases the maximum rated gate voltage.

Further, in the same manner as the first gate portion 24A, in a structure in which the second gate portion 24B forms a Schottky junction with the second gate electrode 26B, the relationship of L3≤T2 is satisfied in the second gate portion 24B. Thus, the ratio of the area of the Schottky junction interface to the area of the upper surface 24BS1 of the second gate portion 24B can be maintained in a satisfactory manner in accordance with thickness T2 of the second gate portion 24B. As a result, the depletion layer that spreads in the vertical direction from the junction interface is also maintained in a satisfactory manner in the horizontal direction with respect to the area of the upper surface 24BS1 of the second gate portion 24B. This increases the maximum rated gate voltage.

(1-4) Length L1 of the first side-space region 24AL1, length L2 of the second side-space region 24AL2, and length LG1 of the first gate electrode 26A satisfy the relationship of LG1≥L1+L2. Further, length L3 of the third side-space region 24BL1, length L4 of the fourth side-space region 24BL2, and length LG2 of the second gate electrode 26B satisfy the relationship of LG2≥L3+L4.

This structure increases the area of the first gate electrode 26A contacting the upper surface 24AS1 of the first gate portion 24A and allows gate signals to be efficiently transmitted from the first gate electrode 26A to the first gate portion 24A. Thus, gate signals can be sufficiently transmitted to the ends of the lower surface 24AS2 of the first gate portion 24A. This improves the subthreshold characteristics. As a result, the drain leakage current is decreased when the gate voltage is less than or equal to the threshold voltage. Further, the first gate electrode 26A has a large cross-sectional area. This allows the gate resistance to be decreased.

In the same manner as the first gate portion 24A, with the second gate portion 24B, the area of the second gate electrode 26B contacting the upper surface 24BS1 of the second gate portion 24B is increased. As a result, the subthreshold characteristics are improved, and the drain leakage current when the gate voltage is less than or equal to the threshold voltage is decreased. Further, the second gate electrode 26B has a large cross-sectional area. This allows the gate resistance to be decreased.

(1-5) The electron transit layer 16 is a GaN layer, the electron supply layer 18 is an AlGaN layer, and the first gate portion 24A and the second gate portion 24B are GaN layers containing acceptor impurities. This inhibits local increases in the current density of the gate leakage current in the GaN-HEMT structure, and increases the maximum rated gate voltage in the positive direction.

(1-6) The first gate electrode 26A forms a Schottky junction with the first gate portion 24A, and the second gate electrode 26B forms a Schottky junction with the second gate portion 24B. With this structure, the surface leakage current (first and second leakage currents Ig1 and Ig2) is dominant over the bulk current (third leakage current Ig3). In this case, in a structure in which the gate-drain distance is greater than the gate-source distance, the path of the first leakage current Ig1 is shorter than the path of the second leakage current Ig2. Thus, the first leakage current Ig1 becomes prominently greater than the second leakage current Ig2. This produces sections in the first and second gate portions 24A and 24B where the gate leakage current increases locally. The asymmetric gate structure satisfying the relationship of L1>L2 and L3>L4 effectively inhibits such local increases in the current density (as compared with, for example, a symmetric gate structure in which L1=L2 and L3=L4 are satisfied).

(1-7) The first FET 30A, which includes the asymmetric gate structure of the first gate electrode 26A and the first gate portion 24A, and the second FET 30B, which includes the asymmetric gate structure of the second gate electrode 26B and the second gate portion 24B, are both normally-off structures. Thus, the first and second FETs 30A and 30B are suitable for use as power transistors from the viewpoint of their fail-safe features.

### Second Embodiment

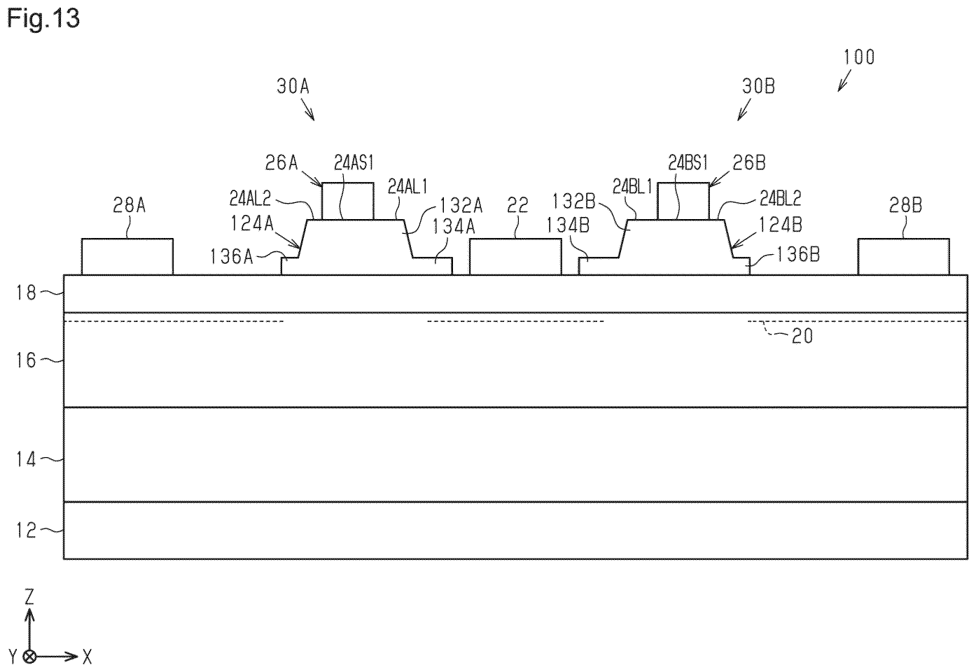

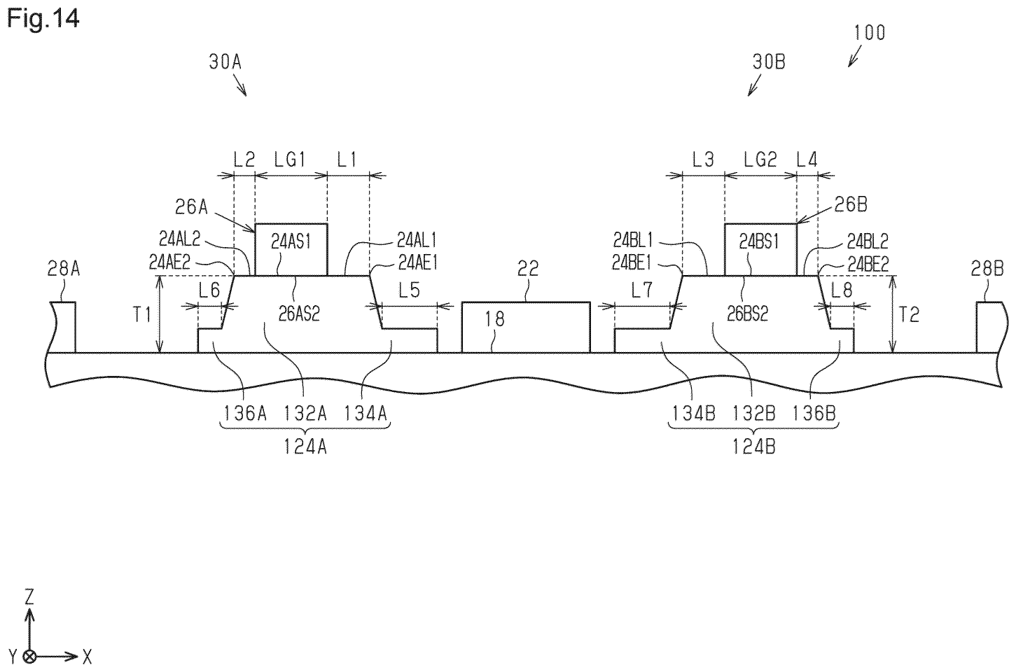

A second embodiment will now be described with reference to FIGS. 13 to 16. FIG. 13 is a schematic cross-sectional view of an exemplary semiconductor device 100 in accordance with the second embodiment. Further, FIG. 14 is a partially enlarged view of the semiconductor device 100 illustrated in FIG. 13. In FIGS. 13 to 15, the same reference characters are given to those elements that are the same as the corresponding elements in the semiconductor device 10 of the first embodiment. Elements that are the same as the corresponding elements in the first embodiment will not be described in detail. The description will focus on differences from the first embodiment.

### Gate Structure of Second Embodiment

As shown in FIG. 13, the semiconductor device 100 of the second embodiment differs from the semiconductor device 10 of the first embodiment in that the first gate portion 24A and the second gate portion 24B are respectively substituted by a first gate portion 124A and a second gate portion 124B. Otherwise, the structure is the same as the first embodiment.

Each of the first and second gate portions 124A and 124B is a semiconductor layer (corresponding to third semiconductor layer) containing acceptor impurities and may be composed of, for example, a nitride semiconductor containing acceptor impurities. The first and second gate portions 124A and 124B may be composed of any semiconductor material having a smaller band gap than the electron supply layer 18. In the second embodiment, each of the first and second gate portions 124A and 124B is a GaN layer, or p-type GaN layer, doped with acceptor impurities. The acceptor impurities may include, for example, at least one of zinc (Zn), magnesium (Mg), and carbon (C). In the second embodiment, Mg is used as the acceptor impurities. The maximum concentration of the acceptor impurities is, for example, 7×10¹⁸ cm⁻³ or greater and 1×10²⁰ cm⁻³ or less.

The first and second gate portions 124A and 124B are not particularly limited in thickness and may be determined taking into consideration, for example, the gate breakdown voltage and the like. For example, the first and second gate portions 124A and 124B may each have a thickness of 80 nm or greater and 150 nm or less. In the second embodiment, the thickness of the first and second gate portions 124A and 124B is approximately 100 nm.

The first gate portion 124A includes a first ridge 132A, a first source-side horizontal extension 134A, and a first drain-side horizontal extension 136A. In the same manner, the second gate portion 124B includes a second ridge 132B, a second source-side horizontal extension 134B, and a second drain-side horizontal extension 136B.

The first and second ridges 132A and 132B are not particularly limited in cross-sectional shape (cross-sectional shape taken along ZX plane in FIG. 13) and may be, for example, rectangular, trapezoidal, or have any other shape. In the second embodiment, the first and second ridges 132A and 132B are trapezoidal in cross section. In this case, the first and second ridges 132A and 132B include inclined side walls that are flared. The first and second ridges 132A and 132B, however, do not have to include such side walls. The first ridge 132A may be connected to each of the horizontal extensions 134A and 136A by a separate inclined part serving as an extension or by part of the first ridge 132A. The second ridge 132B may be connected to each of the horizontal extensions 134B and 136B by a separate inclined part serving as an extension or by part of the second ridge 132B.

The first ridge 132A corresponds to or is similar to the first gate portion 24A of the first embodiment. Thus, the first gate portion 124A of the second embodiment corresponds to a structure in which the first source-side horizontal extension 134A and the first drain-side horizontal extension 136A are added to the first gate portion 24A of the first embodiment, which corresponds to the first ridge 132A.

In the same manner, the second ridge 132B corresponds to or is similar to the second gate portion 24B of the first embodiment. Thus, the second gate portion 124B of the second embodiment corresponds to a structure in which the second source-side horizontal extension 134B and the second drain-side horizontal extension 136B are added to the second gate portion 24B of the first embodiment, which corresponds to the second ridge 132B.

To aid understanding, elements of the first and second ridges 132A and 132B corresponding to the elements of the first and second gate portions 24A and 24B will be described using the same reference characters as the elements of the first and second gate portions 24A and 24B.

The upper surface 24AS1 of the first gate portion 124A corresponds to the upper surface of the first ridge 132A, and the first gate electrode 26A is arranged on the upper surface 24AS1 of the first ridge 132A (first gate portion 124A). The relationship of the first ridge 132A and the first gate electrode 26A in the second embodiment corresponds to the relationship of the first gate portion 24A and the first gate electrode 26A in the first embodiment.

Thus, as shown in FIG. 14, in the same manner as the first embodiment, the upper surface 24AS1 of the first ridge 132A includes the first side-space region 24AL1, which has length L1, and the second side-space region 24AL2, which has length L2. Further, in the same manner as the first embodiment, lengths L1 and L2 satisfy the relationship of L1>L2, more preferably, the relationship of L1≥2×L2.

In the same manner, the upper surface 24BS1 of the second gate portion 124B corresponds to the upper surface of the second ridge 132B, and the second gate electrode 26B is arranged on the upper surface 24BS1 of the second ridge 132B (second gate portion 124B). The relationship of the second ridge 132B and the second gate electrode 26B in the first embodiment corresponds to the relationship of the second gate portion 24B and the second gate electrode 26B in the first embodiment.

Thus, as shown in FIG. 14, in the same manner as the first embodiment, the upper surface 24BS1 of the second ridge 132B includes the third side-space region 24BL1, which has length L3, and the fourth side-space region 24BL2, which has length L4. Further, in the same manner as the first embodiment, lengths L3 and L4 satisfy the relationship of L3>L4, more preferably, L3≥2×L4.

The first source-side horizontal extension 134A of the first gate portion 124A extends horizontally from the first ridge 132A toward the source electrode 22 (in X-direction) over length L5. The first drain-side horizontal extension 136A extends horizontally from the first ridge 132A toward the first drain electrode 28A (in X-direction) over length L6.

Length L5 of the first source-side horizontal extension 134A is greater than length L6 of the first drain-side horizontal extension 136A. Thus, length L5 and length L6 are set to satisfy the relationship of L5>L6, more preferably, the relationship of L6<L5<2×L6. Length L5 of the first source-side horizontal extension 134A may be, for example, 0.2 μm or greater and 0.6 μm or less. Length L6 of the first drain-side horizontal extension 136A may be, for example, 0.2 μm or greater and 0.3 μm or less. The first source-side horizontal extension 134A and the first drain-side horizontal extension 136A may have the same thickness of, for example, 5 nm or greater and 25 nm or less.

In the same manner, the second source-side horizontal extension 134B of the second gate portion 124B extends horizontally from the second ridge 132B toward the source electrode 22 (in X-direction) over length L7. The second drain-side horizontal extension 136B extends horizontally from the second ridge 132B toward the second drain electrode 28B (in X-direction) over length L8.

Length L7 of the second source-side horizontal extension 134B is greater than length L8 of the second drain-side horizontal extension 136B. Thus, length L7 and length L8 are set to satisfy the relationship of L7>L8, more preferably, the relationship of L8<L7≤2×L8. Length L7 of the second source-side horizontal extension 134B may be, for example, 0.2 μm or greater and 0.6 μm or less. Length L8 of the second drain-side horizontal extension 136B may be, for example, 0.2 μm or greater and 0.3 μm or less. The second source-side horizontal extension 134B and the second drain-side horizontal extension 136B may have the same thickness of, for example, 5 nm or greater and 25 nm or less.

Length L5 of the first source-side horizontal extension 134A may be the same as length L7 of the second source-side horizontal extension 134B (i.e., L5=L7). Further, length L6 of the first drain-side horizontal extension 136A may be the same as length L8 of the second drain-side horizontal extension 136B (i.e., L6-L8).

### Relationship of Gate Structure and Gate Leakage Current in Second Embodiment

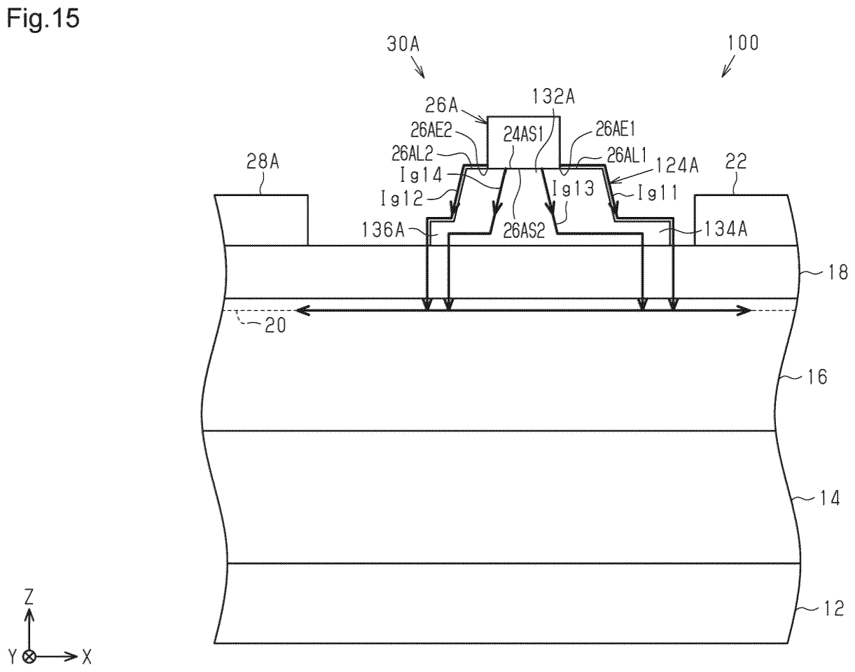

The relationship of the gate structure and the gate leakage current in the second embodiment will now be described with reference to FIG. 15.

FIG. 15 is a partially enlarged view of the semiconductor device 100 illustrated in FIG. 13 and shows gate leakage current paths in the first FET 30A of the second embodiment. Although the description will focus on the first FET 30A, the same applies to the second FET 30B.

In the gate structure of the second embodiment, when positive voltage is applied to the first gate electrode 26A, first to fourth leakage currents Ig11, Ig12, Ig13, and Ig14 flow through the first gate portion 124A from the lower surface 26AS2 of the first gate electrode 26A toward the 2DEG 20 along the four paths described below.

The first leakage current Ig11 is current that flows from the first source-side electrode end 26AE1 of the first gate electrode 26A along the first side-space region AL1 of the first ridge 132A, the side surface of the first ridge 132A (side surface located toward source electrode 22), and the surface of the first source-side horizontal extension 134A and then toward the 2DEG 20.

The second leakage current Ig12 is current that flows from the first drain-side electrode end 26AE2 of the first gate electrode 26A along the second side-space region AL2 of the first ridge 132A, the side surface of the first ridge 132A (side surface located toward first drain electrode 28A), and the surface of the first drain-side horizontal extension 136A and then toward the 2DEG 20.

The third leakage current Ig13 is current that flows from the lower surface 26AS2 of the first gate electrode 26A through the inside of the first ridge 132A and the inside of the first source-side horizontal extension 134A and then toward the 2DEG 20.

The fourth leakage current Ig14 is current that flows from the lower surface 26AS2 of the first gate electrode 26A through the inside of the first ridge 132A and the inside of the first drain-side horizontal extension 136A and then toward the 2DEG 20.

When voltage greater than or equal to the threshold value is applied to the first gate electrode 26A and the 2DEG 20 is being generated, the second and fourth leakage currents Ig12 and Ig14 are each divided into current that flows through the 2DEG 20 toward the source electrode 22 and current that flows through the 2DEG 20 toward the first drain electrode 28A. Most of the first and third leakage currents Ig11 and Ig13 flow through the 2DEG 20 toward the source electrode 22.

Thus, the section of the first gate portion 124A located underneath the first source-side electrode end 26AE1 of the first gate electrode 26A is where more gate leakage current concentrates than other locations. To inhibit such local increase in current density, the first gate portion 124A of the second embodiment includes the first source-side horizontal extension 134A and the first drain-side horizontal extension 136A in addition to the first ridge 132A.

For example, if the first gate portion 124A were to have a gate structure including only the first ridge 132A, when a large positive voltage is applied to the first gate electrode 26A, an electric field will concentrate at the end of the first ridge 132A in the interface of the first ridge 132A and the electron supply layer 18.

In this regard, with the gate structure of the second embodiment in which the first gate portion 124A includes the first source-side horizontal extension 134A and the first drain-side horizontal extension 136A in addition to the first ridge 132A, the interface of the first gate portion 124A and the electron supply layer 18 has a large area. Thus, in contrast with a gate structure in which the first gate portion 124A includes only the first ridge 132A, electric field concentration is inhibited at the end of the first gate portion 124A.

As a result, the flow of current is limited along the surface of the first gate portion 124A. This decreases the first and second leakage currents Ig11 and Ig12 (surface leakage current). More specifically, the third and fourth leakage currents Ig13 and Ig14 (bulk leakage current) are relatively increased to decrease the first and second leakage currents Ig11 and Ig12. This decreases the current density of the gate leakage current at the section of the first gate portion 124A located underneath the first source-side electrode end 26AE1 and increases the maximum rated gate voltage in the positive direction.

In addition, the thickness of the first source-side horizontal extension 134A and the thickness of the first drain-side horizontal extension 136A are less than the thickness of the first ridge 132A. Thus, the turn-on voltage of a PIN diode formed by the first gate portion 124A (in this case, p-type GaN layer), the electron supply layer 18 (in this case, AlGaN layer), and the 2DEG 20 is smaller in the region of the first source-side horizontal extension 134A and the first drain-side horizontal extension 136A than in the region of the first ridge 132A.

As a result, the gate voltage applied to the first gate electrode 26A causes the third leakage current Ig13 to flow inside the first source-side horizontal extension 134A and the fourth leakage current Ig14 to flow inside the first drain-side horizontal extension 136A. This increases the breakdown voltage at the Schottky junction of the first gate electrode 26A and the first gate portion 124A and increases the maximum rated gate voltage in the positive direction.

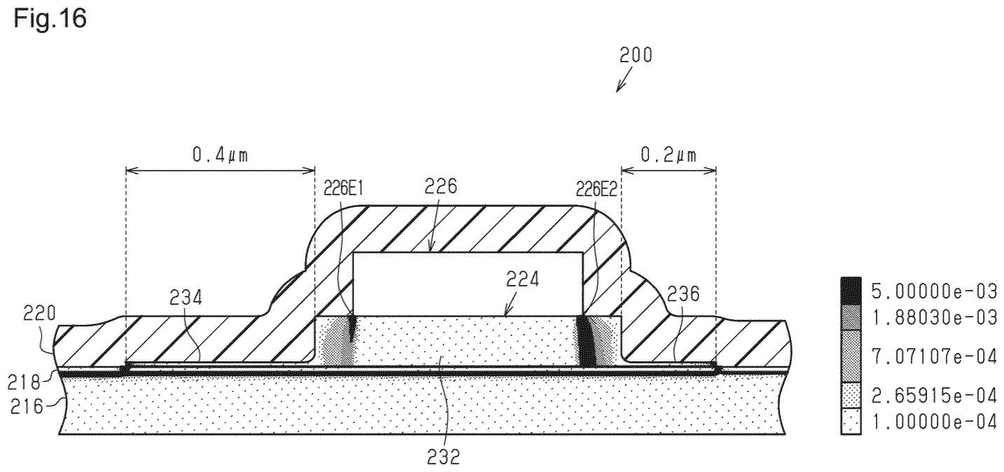

Further, as described above, length L5 of the first source-side horizontal extension 134A and length L6 of the first drain-side horizontal extension 136A satisfies the relationship of L5>L6. Thus, the third leakage current Ig13 is less than the fourth leakage current Ig14. This operation will now be described with reference to FIG. 16.

FIG. 16 is a cross-sectional view illustrating a simulation result of the current density of the bulk leakage current flowing through the gate structure of the second embodiment. As shown in FIG. 16, the semiconductor device 100 used in the simulation includes an electron transit layer 216 (GaN layer), an electron supply layer 218 (AlGaN layer) on the electron transit layer 216, a gate portion 224 (p-type GaN layer) on the electron supply layer 218, a gate electrode 226 (TiN layer) on the gate portion 224, and a passivation layer 220. The gate portion 224 includes a ridge 232, a source-side horizontal extension 234, and a drain-side horizontal extension 236.

The electron transit layer 216, the electron supply layer 218, the gate portion 224, and the gate electrode 226 respectively correspond to, for example, the electron transit layer 16, the electron supply layer 18, the first gate portion 124A, and the first gate electrode 26A that are shown in FIGS. 13 to 15. Further, the ridge 232, the source-side horizontal extension 234, and the drain-side horizontal extension 236 of the gate portion 224 respectively correspond to, for example, the first ridge 132A, the first source-side horizontal extension 134A, and the first drain-side horizontal extension 136A of the first gate portion 124A.

In the simulation, the current density distribution of the bulk leakage current flowing from the gate electrode 226 to the gate portion 224 was checked when applying positive voltage (e.g., 23 V) to the gate electrode 226. In this simulation, the surface leakage current was not checked. The length of the source-side horizontal extension 234 (e.g., length L5 of first source-side horizontal extension 134A) was 0.4 μm, and the length of the drain-side horizontal extension 236 (e.g., length L6 of first drain-side horizontal extension 136A) was 0.2 μm.

As shown in FIG. 16, the bulk leakage current flowing from a source-side electrode end 226E1 of the gate electrode 226 is smaller than the bulk leakage current flowing from a drain-side electrode end 226E2 of the gate electrode 226. It is understood that this is because the length of the source-side horizontal extension 234 being greater than the length of the drain-side horizontal extension 236 inhibits the electric field at the distal end of the source-side horizontal extension 234 and decreases the current flowing in the source-side horizontal extension 234.

Accordingly, in the structure of the first FET 30A shown in FIGS. 13 and 15, length L5 of the first source-side horizontal extension 134A is greater than length L6 of the first drain-side horizontal extension 136A so that the third leakage current Ig13 is less than the fourth leakage current Ig14. As a result, the current density of the gate leakage current is decreased at the section of the first gate portion 124A located underneath the first source-side electrode end 26AE1. This increases the maximum rated gate voltage in the positive direction.

Further, length L5 and length L6 are set to satisfy the relationship of L6<L5≤2×L6. This limits increases in the source resistance when increasing length L5 of the first source-side horizontal extension 134A.

In the same manner as the first embodiment, in the second embodiment, the first gate electrode 26A is arranged on the upper surface 24AS1 of the first ridge 132A (first gate portion 124A) to form an asymmetric gate structure satisfying the relationship of L1>L2. Thus, the first leakage current Ig11 is also decreased in the same manner as the first embodiment. As a result, the decrease in the first leakage current Ig11 and the third leakage current Ig13 further deceases the current density of the gate leakage current at the section of the first gate portion 124A located underneath the first source-side electrode end 26AE1 and increases the maximum rated gate voltage in the positive direction.

In the first gate portion 124A, the acceptor impurity concentration of the first ridge 132A may be less than the acceptor impurity concentration of the first source-side horizontal extension 134A and the first drain-side horizontal extension 136A. For example, the first ridge 132A may be doped with Mg at a first concentration, and the first source-side horizontal extension 134A and the first drain-side horizontal extension 136A may be doped with Mg at a second concentration that is less than the first concentration. In this case, the first concentration and the second concentration may be, for example, the maximum concentration at each region doped with acceptor impurities.

In this manner, by forming the first gate portion 124A with different impurity concentrations, the bulk current flowing through the first source-side horizontal extension 134A and the first drain-side horizontal extension 136A (i.e., third and fourth leakage currents Ig13 and Ig14) can be decreased. This further decreases the current density of the gate leakage current at the section of the first gate portion 124A located underneath the first source-side electrode end 26AE1 and increases the maximum rated gate voltage in the positive direction.

The description hereabove is also applied to the second gate portion 124B, which has the same structure as the first gate portion 124A. When the first gate portion 124A is formed with different impurity concentrations as described above, the second gate portion 124B is also formed with different impurity concentrations.

The method for manufacturing the semiconductor device 100 of the second embodiment will not be described in detail. The method for manufacturing the semiconductor device 10 of the first embodiment described with reference to FIGS. 4 to 12 can be applied. For example, after the step of FIG. 10, the step of forming the first ridge 132A (second ridge 132B) is performed. Then, the step of forming the first source-side horizontal extension 134A (second source-side horizontal extension 134B) and the first drain-side horizontal extension 136A (second drain-side horizontal extension 136B) is performed. This forms the first gate portion 124A (second gate portion 124B) shown in FIGS. 13 to 15.

In addition to advantages (1-1) to (1-7) of the first embodiment, the semiconductor device 100 has the advantages described below.

(2-1) The first gate portion 124A includes the first source-side horizontal extension 134A, which extends from the first ridge 132A over length L5, and the first drain-side horizontal extension 136A, which extends from the first ridge 132A over length L6. Further, the second gate portion 124B includes the second source-side horizontal extension 134B, which extends from the second ridge 132B over length L7, and the second drain-side horizontal extension 136B, which extends from the second ridge 132B over length L8.

This structure inhibits electric field concentration at the end of the first gate portion 124A and is in contrast with a structure in which the first gate portion 124A includes only the first ridge 132A. As a result, the flow of current is limited along the surface of the first gate portion 124A. This decreases the first and second leakage currents Ig11 and Ig12 (surface leakage current). Thus, the current density of the gate leakage current is decreased at the section of the first gate portion 124A located underneath the first source-side electrode end 26AE1, and the maximum rated gate voltage in the positive direction is increased.

Further, in the same manner as the first gate portion 124A, in the second gate portion 124B, electric field concentration is inhibited at the end of the first gate portion 124A, and the first and second leakage currents Ig11 and Ig12 (surface leakage current) is decreased. Thus, the current density of the gate leakage current is decreased at the section of the second gate portion 124B located underneath the second source-side electrode end 26BE1, and the maximum rated gate voltage in the positive direction is increased.

(2-2) Length L5 and length L6 satisfy the relationship of L5>L6, and length L7 and length L8 satisfy the relationship of L7>L8. This structure inhibits the electric field at the distal end of the first source-side horizontal extension 134A of the first gate portion 124A, and decreases the bulk leakage current flowing in the first source-side horizontal extension 134A. As a result, the third leakage current Ig13 is less than the fourth leakage current Ig14. Thus, the current density of the gate leakage current is decreased at the section of the first gate portion 124A located underneath the first source-side electrode end 26AE1, and the maximum rated gate voltage in the positive direction is increased.

Further, in the same manner as the first gate portion 124A, in the second gate portion 124B, the electric field density is inhibited at the distal end of the second source-side horizontal extension 134B, and the bulk leakage current flowing in the second source-side horizontal extension 134B is decreased. Thus, the current density of the gate leakage current is decreased at the section of the second gate portion 124B located underneath the second source-side electrode end 26BE1, and the maximum rated gate voltage in the positive direction is increased.

(2-3) Length L5 and length L6 satisfy the relationship of L6<L5≤2×L6, and length L7 and length L8 satisfy the relationship of L8<L7≤2×L8. This structure limits increases in the source resistance when increasing length L5 of the first source-side horizontal extension 134A. In the same manner, increases in the source resistance are limited when increasing length L7 of the second source-side horizontal extension 134B.

(2-4) In the first gate portion 124A, the concentration of the doped acceptor impurities in the first ridge 132A is less than the concentration of the doped acceptor impurities in the first source-side horizontal extension 134A and the first drain-side horizontal extension 136A. In the same manner, in the second gate portion 124B, the concentration of the doped acceptor impurities in the second ridge 132B is less than the concentration of the doped acceptor impurities in the second source-side horizontal extension 134B and the second drain-side horizontal extension 136B.

This structure decreases the bulk leakage current flowing through the first source-side horizontal extension 134A and the first drain-side horizontal extension 136A and decreases the bulk leakage current flowing through the second source-side horizontal extension 134B and the second drain-side horizontal extension 136B. Thus, the effect for decreasing the current density of the gate leakage current is further increased, and the maximum rated gate voltage in the positive direction is increased.

### Modified Examples

The above embodiments may be modified as described below. The above-described embodiments and the modified examples described below may be combined as long as there is no technical contradiction.

The semiconductor device 10 is not limited to a device that uses GaN. For example, a nitride semiconductor such as AlN or InN may be used instead of GaN. Further, the semiconductor device 10 does not have to be a HEMT that uses a nitride semiconductor and may be a HEMT that uses a group III-V semiconductor.

The gate structure of the semiconductor device 100 in the second embodiment is formed to have the asymmetric gate structure of the semiconductor device 10 of the first embodiment (i.e., satisfy the relationship of L1>L2 and L3>L4). However, the relationship of L1>L2 and L3>L4 does not have to be satisfied. That is, the first side-space region 24AL1 and the second side-space region 24AL2 in the first gate portion 124A may satisfy the relationship of L1=L2, and the third side-space region 24BL1 and the fourth side-space region 24BL2 in the second gate portion 124B may satisfy the relationship of L3=L4. Further, other features of the first embodiment may be omitted from the second embodiment.

In the gate structure of each embodiment, the first gate electrode 26A (second gate electrode 26B) forms a Schottky junction with the first gate portion 24A (the second gate portion 24B). However, there is no limitation to a gate structure formed by a Schottky junction. For example, the gate structure may be formed by an ohmic junction.

In this specification, the word “on” includes the meaning of “above” in addition to the meaning of “on” unless otherwise described in the context. Accordingly, the phrase of “first layer formed on second layer” may mean that the first layer is formed directly contacting the second layer in one embodiment and that the first layer is arranged above the second layer without contacting the second layer in another embodiment. Thus, the word “on” will also allow for a structure in which another layer is arranged between the first layer and the second layer. For example, in each of the above embodiments, the electron supply layer 18 is formed on the electron transit layer 16. This means that an intermediate layer may be located between the electron supply layer 18 and the electron transit layer 16 to stably form the 2DEG 20.

The Z-axis direction as referred to in this specification does not necessarily have to be the vertical direction and does not necessarily have to fully coincide with the vertical direction. Accordingly, in the structures disclosed above (e.g., structure shown in FIG. 1), upward and downward in the Z-axis direction as referred to in this specification is not limited to upward and downward in the vertical direction. For example, the X-axis direction may be the vertical direction. Alternatively, the Y-axis direction may be the vertical direction.

The terms used in this specification to indicate directions such as vertical, horizontal, upward, downward, up, down, forward, rearward, side, left, right, front, and back will be attributed to specific directions of the described and illustrated device. In this disclosure, a variety of alternative directions may be available for any given direction. Thus, directional terms should not be construed narrowly.

### Clauses

Technical concepts that can be understood from each of the above embodiments and modified examples will now be described. The reference characters used to denote elements of the embodiments are shown in parenthesis for the corresponding elements of the clauses described below. The reference characters are given as examples to aid understanding and not intended to limit elements to the elements denoted by the reference characters.

### [Clause A1]

A semiconductor device (10; 100), including:
a substrate (12);
a first semiconductor layer (16) arranged above the substrate (12);
a second semiconductor layer (18) arranged on the first semiconductor layer (16) to generate two-dimensional electron gas (20) in the first semiconductor layer (16) proximate to an interface of the first semiconductor layer (16) and the second semiconductor layer (18);
a source electrode (22) arranged on the second semiconductor layer (18);
a first gate portion (24A; 124A) formed by a third semiconductor layer containing acceptor impurities, the first gate portion (24A; 124A) being arranged on the second semiconductor layer (18);
a second gate portion (24B; 124B) formed by the third semiconductor layer containing the acceptor impurities, the second gate portion (24B; 124B) being arranged on the second semiconductor layer (18) at a side of the source electrode (22) opposite the first gate portion (24A; 124A);
a first gate electrode (26A) arranged on part of the first gate portion (24A; 124A);
a second gate electrode (26B) arranged on part of the second gate portion (24B; 124B);
a first drain electrode (28A) arranged on the second semiconductor layer (18) at a side of the first gate portion (24A; 124A) opposite the source electrode (22); and
a second drain electrode (28B) arranged on the second semiconductor layer (18) at a side of the second gate portion (24B; 124B) opposite the source electrode (22), where
the first gate portion (24A; 124A) has an upper surface (24AS1) including a first source-side end (24AE1) located toward the source electrode (22) and a first drain-side end (24AE2) located toward the first drain electrode (28A),
the first gate electrode (26A) has a lower surface (26AS2) including a first source-side electrode end (26AE1) located toward the source electrode (22) and a first drain-side electrode end (26AE2) located toward the first drain electrode (28A),
the second gate portion (24B; 124B) has an upper surface (24BS1) including a second source-side end (24BE1) located toward the source electrode (22) and a second drain-side end (24BE2) located toward the second drain electrode (28B),
the second gate electrode (26B) has a lower surface (26BS2) including a second source-side electrode end (26BE1) located toward the source electrode (22) and a second drain-side electrode end (26BE2) located toward the second drain electrode (28B),
the upper surface (24AS1) of the first gate portion (24A; 124A) includes
   a first side-space region (24AL1) extending over length L1 corresponding to a distance between the first source-side end (24AE1) and the first source-side electrode end (26AE1), and
   a second side-space region (24AL2) extending over length L2 corresponding to a distance between the first drain-side end (24AE2) and the first drain-side electrode end (26AE2),
the upper surface (24BS1) of the second gate portion (24B; 124B) includes
   a third side-space region (24BL1) extending over length L3 corresponding to a distance between the second source-side end (24BE1) and the second source-side electrode end (26BE1), and
   a fourth side-space region (24BL2) extending over length L4 corresponding to a distance between the second drain-side end (24BE2) and the second drain-side electrode end (26BE2),
the length L1 and the length L2 satisfy a relationship of L1>L2, and
the length L3 and the length L4 satisfy a relationship of L3>L4.

### [Clause A2]

The semiconductor device (10; 100) according to clause A1, where:
the length L1 and the length L2 satisfy a relationship of L1≥2×L2; and
the length L3 and the length L4 satisfy a relationship of L3≥2×L4.

### [Clause A3]

The semiconductor device (10; 100) according to clause A1 or A2, where:
the first gate portion (24A; 124A) has thickness T1 from the upper surface (24AS1) of the first gate portion (24A; 124A) to a lower surface (24AS2) of the first gate portion (24A; 124A);
the second gate portion (24B; 124B) has thickness T2 from the upper surface (24BS1) of the second gate portion (24B; 124B) to a lower surface (24BS2) of the second gate portion (24B; 124B);
the length L1 and the thickness T1 satisfy a relationship of L1≤T1; and
the length L3 and the thickness T2 satisfy a relationship of L3≤T2.

### [Clause A4]

The semiconductor device (10; 100) according to any one of clauses A1 to A3, where:
the first gate electrode (26A) has length LG1 from the first source-side electrode end (26AE1) to the first drain-side electrode end (26AE2);
the second gate electrode (26B) has length LG2 from the second source-side electrode end (26BE1) to the second drain-side electrode end (26BE2);
the length L1, the length L2, and the length LG1 satisfy a relationship of LG1≥L1+L2; and
the length L3, the length L4, and the length LG2 satisfy a relationship of LG2≥L3+L4.

### [Clause A5]

The semiconductor device (100) according to any one of clauses A1 to A4, where:
the first gate portion (124A) includes
   a first ridge (132A) including the upper surface (24AS1) of the first gate portion (124A),
   a first source-side horizontal extension (134A) extending horizontally from the first ridge (132A) toward the source electrode (22), and
   a first drain-side horizontal extension (136A) extending horizontally from the first ridge (132A) toward the first drain electrode (28A); and
the second gate portion (124B) includes
   a second ridge (132B) including the upper surface (24BS1) of the second gate portion (124B),
   a second source-side horizontal extension (134B) extending horizontally from the second ridge (132B) toward the source electrode (22), and
   a second drain-side horizontal extension (136B) extending horizontally from the second ridge (132B) toward the second drain electrode (28B).

### [Clause A6]

The semiconductor device (100) according to clause A5, where:
the first source-side horizontal extension (134A) extends from the first ridge (132A) toward the source electrode (22) over length L5;
the first drain-side horizontal extension (136A) extends from the first ridge (132A) toward the first drain electrode (28A) over length L6;
the second source-side horizontal extension (134B) extends from the second ridge (132B) toward the source electrode (22) over length L7;
the second drain-side horizontal extension (136B) extends from the second ridge (132B) toward the second drain electrode (28B) over length L8;
the length L5 and the length L6 satisfy a relationship of L5>L6; and
the length L7 and the length L8 satisfy a relationship of L7>L8.

### [Clause A7]

The semiconductor device (100) according to clause A6, where:
the length L5 and the length L6 satisfy a relationship of L6<L5≤2×L6; and
the length L7 and the length L8 satisfy a relationship of L8<L7≤2×L8.

### [Clause A8]

The semiconductor device (100) according to clause A6 or A7, where:
the length L5 and the length L7 satisfy a relationship of L5-L7; and
the length L6 and the length L8 satisfy a relationship of L6=L8.

### [Clause A9]

The semiconductor device (100) according to any one of clauses A5 to A8, where:
the first ridge (132A) and the second ridge (132B) contain the acceptor impurities at a first concentration; and
the first source-side horizontal extension (134A), the first drain-side horizontal extension (136A), the second source-side horizontal extension (134B), and the second drain-side horizontal extension (136B) contain the acceptor impurities at a second concentration that is less than the first concentration.

### [Clause A10]

The semiconductor device (10; 100) according to any one of clauses A1 to A9, where:
the first semiconductor layer (16) is a GaN layer;
the second semiconductor layer (18) is an AlGaN layer; and
the first gate portion (24A; 124A) and the second gate portion (24B; 124B) are each a GaN layer containing the acceptor impurities.

### [Clause A11]

The semiconductor device (10; 100) according to any one of clauses A1 to A10, where:
the first gate electrode (26A) forms a Schottky junction with the first gate portion (24A; 124A); and
the second gate electrode (26B) forms a Schottky junction with the second gate portion (24B; 124B).

### [Clause A12]

The semiconductor device (10; 100) according to any one of clauses A1 to A11, where:
the first semiconductor layer (16), the second semiconductor layer (18), the first gate portion (24A; 124A), the first gate electrode (26A), the source electrode (22), and the first drain electrode (28A) form a first field-effect transistor (30A);
the first semiconductor layer (16), the second semiconductor layer (18), the second gate portion (24B; 124B), the second gate electrode (26B), the source electrode (22), and the second drain electrode (28B) form a second field-effect transistor (30B); and
the first field-effect transistor (30A) and the second field-effect transistor (30B) are of a normally-off type.

### [Clause A13]

The semiconductor device (10; 100) according to any one of clauses A1 to A11, where:
the length L1 and the length L3 satisfy a relationship of L1-L3; and
the length L2 and the length L4 satisfy a relationship of L2=L4.

### [Clause A14]

A semiconductor device (100), including:
a substrate (12);
a first semiconductor layer (16) arranged above the substrate (12);
a second semiconductor layer (18) arranged on the first semiconductor layer (16) to generate two-dimensional electron gas (20) in the first semiconductor layer (16) proximate to an interface of the first semiconductor layer (16) and the second semiconductor layer (18);
a source electrode (22) arranged on the second semiconductor layer (18);
a first gate portion (124A) formed by a third semiconductor layer containing acceptor impurities, the first gate portion (124A) being arranged on the second semiconductor layer (18);
a second gate portion (124B) formed by the third semiconductor layer containing the acceptor impurities, the second gate portion (124B) being arranged on the second semiconductor layer (18) at a side of the source electrode (22) opposite the first gate portion (124A);
a first gate electrode (26A) arranged on part of the first gate portion (124A);
a second gate electrode (26B) arranged on part of the second gate portion (124B);
a first drain electrode (28A) arranged on the second semiconductor layer (18) at a side of the first gate portion (124A) opposite the source electrode (22); and
a second drain electrode (28B) arranged on the second semiconductor layer (18) at a side of the second gate portion (124B) opposite the source electrode (22), where
the first gate portion (124A) includes
   a first ridge (132A),
   a first source-side horizontal extension (134A) extending horizontally from the first ridge (132A) toward the source electrode (22) over length L5, and
   a first drain-side horizontal extension (136A) extending horizontally from the first ridge (132A) toward the first drain electrode (28A) over length L6,
the second gate portion (124B) includes
   a second ridge (132B),
   a second source-side horizontal extension (134B) extending horizontally from the second ridge (132B) toward the source electrode (22) over length L7, and
   a second drain-side horizontal extension (136B) extending horizontally from the second ridge (132B) toward the second drain electrode (28B) over length L8,
the length L5 and the length L6 satisfy a relationship of L5>L6, and
the length L7 and the length L8 satisfy a relationship of L7>L8.

### [Clause A15]

The semiconductor device (100) according to clause A14, where:
the length L5 and the length L6 satisfy a relationship of L6<L5≤2×L6; and
the length L7 and the length L8 satisfy a relationship of L8<L7≤2×L8.

### [Clause A16]

The semiconductor device (100) according to clause A14 or A15, where:
the length L5 and the length L7 satisfy a relationship of L5-L7; and
the length L6 and the length L8 satisfy a relationship of L6=L8.

### [Clause A17]

The semiconductor device (100) according to any one of clauses A14 to A16, where:
the first ridge (132A) and the second ridge (132B) contain the acceptor impurities at a first concentration; and
the first source-side horizontal extension (134A), the first drain-side horizontal extension (136A), the second source-side horizontal extension (134B), and the second drain-side horizontal extension (136B) contain the acceptor impurities at a second concentration that is less than the first concentration.

### [Clause A18]

The semiconductor device (100) according to any one of clauses A14 to A17, where:
the first semiconductor layer (16) is a GaN layer;
the second semiconductor layer (18) is an AlGaN layer; and
the first gate portion (124A) and the second gate portion (124B) are each a GaN layer containing the acceptor impurities.

### [Clause A19]

The semiconductor device (100) according to any one of clauses A14 to A18, where:
the first gate electrode (26A) forms a Schottky junction with the first gate portion (124A); and
the second gate electrode (26B) forms a Schottky junction with the second gate portion (124B).

### [Clause A20]

The semiconductor device (100) according to any one of clauses A14 to A19, where:
the first semiconductor layer (16), the second semiconductor layer (18), the first gate portion (124A), the first gate electrode (26A), the source electrode (22), and the first drain electrode (28A) form a first field-effect transistor (30A);
the first semiconductor layer (16), the second semiconductor layer (18), the second gate portion (124B), the second gate electrode (26B), the source electrode (22), and the second drain electrode (28B) form a first field-effect transistor (30B);
the first field-effect transistor (30A) and the second field-effect transistor (30B) are of a normally-off type.

### [Clause B1]

A semiconductor device (10; 100), including:
a substrate (12);
a first semiconductor layer (16) arranged above the substrate (12);
a second semiconductor layer (18) arranged on the first semiconductor layer (16) to generate two-dimensional electron gas (20) in the first semiconductor layer (16) proximate to an interface of the first semiconductor layer (16) and the second semiconductor layer (18);
a source electrode (22) arranged on the second semiconductor layer (18);
a gate portion (24A; 124A; 24B; 124B) formed by a third semiconductor layer containing acceptor impurities, the gate portion (24A; 124A; 24B; 124B) being arranged on the second semiconductor layer (18);
a gate electrode (26A; 26B) arranged on part of the gate portion (24A; 124A; 24B; 124B); and
a drain electrode (28A; 28B) arranged on the second semiconductor layer (18) at a side of the gate portion (24A; 124A; 24B; 124B) opposite the source electrode (22), where
the gate portion (24A; 124A; 24B; 124B) has an upper surface (24AS1; 24BS1) including a source-side end (24AE1; 24BE1) located toward the source electrode (22) and a drain-side end (24AE2; 24BE2) located toward the drain electrode (28A),
the gate electrode (26A; 26B) has a lower surface (26AS2; 26BS2) including a source-side electrode end (26AE1; 26BE1) located toward the source electrode (22) and a drain-side electrode end (26AE2; 26BE2) located toward the drain electrode (28A),
the upper surface (24AS1; 24BS1) of the gate portion (24A; 124A; 24B; 124B) includes
   a first side-space region (24AL1; 24BL1) extending over length L1 corresponding to a distance between the source-side end (24AE1; 24BE1) and the source-side electrode end (26AE1; 26BE1), and
   a second side-space region (24AL2; 24BL2) extending over length L2 corresponding to a distance between the drain-side end (24AE2; 24BE2) and the drain-side electrode end (26AE2; 26BE2), and
the length L1 and the length L2 satisfy a relationship of L1>L2.

### [Clause C1]

A semiconductor device (100), including:
a substrate (12);
a first semiconductor layer (16) arranged above the substrate (12);
a second semiconductor layer (18) arranged on the first semiconductor layer (16) to generate two-dimensional electron gas (20) in the first semiconductor layer (16) proximate to an interface of the first semiconductor layer (16) and the second semiconductor layer (18);
a source electrode (22) arranged on the second semiconductor layer (18);
a gate portion (124A; 124B) formed by a third semiconductor layer containing acceptor impurities, the gate portion (124A; 124B) being arranged on the second semiconductor layer (18);
a gate electrode (26A; 26B) arranged on part of the gate portion (124A; 124B); and
a drain electrode (28A; 28B) arranged on the second semiconductor layer (18) at a side of the gate portion (124A; 124B) opposite the source electrode (22), where
the gate portion (124A; 124B) includes
   a ridge (132A; 132B),
   a source-side horizontal extension (134A; 134B) extending horizontally from the ridge (132A; 132B) toward the source electrode (22) over length L5, and
   a drain-side horizontal extension (136A; 136B) extending horizontally from the ridge (132A; 132B) toward the drain electrode (28A) over length L6, and the length L5 and the length L6 satisfy a relationship of L5>L6.

Exemplary descriptions are given above. In addition to the elements and methods (manufacturing processes) described to illustrate the technology of this disclosure, a person skilled in the art would recognize the potential for a wide variety of combinations and substitutions. All replacements, modifications, and variations within the scope of the claims are intended to be encompassed in the present disclosure.

1. A semiconductor device, comprising:
a substrate;
a first semiconductor layer arranged above the substrate;
a second semiconductor layer arranged on the first semiconductor layer to generate two-dimensional electron gas in the first semiconductor layer proximate to an interface of the first semiconductor layer and the second semiconductor layer;
a source electrode arranged on the second semiconductor layer;
a first gate portion formed by a third semiconductor layer containing acceptor impurities, the first gate portion being arranged on the second semiconductor layer;
a second gate portion formed by the third semiconductor layer containing the acceptor impurities, the second gate portion being arranged on the second semiconductor layer at a side of the source electrode opposite the first gate portion;
a first gate electrode arranged on part of the first gate portion;
a second gate electrode arranged on part of the second gate portion;
a first drain electrode arranged on the second semiconductor layer at a side of the first gate portion opposite the source electrode; and
a second drain electrode arranged on the second semiconductor layer at a side of the second gate portion opposite the source electrode, wherein
the first gate portion has an upper surface including a first source-side end located toward the source electrode and a first drain-side end located toward the first drain electrode,
the first gate electrode has a lower surface including a first source-side electrode end located toward the source electrode and a first drain-side electrode end located toward the first drain electrode,
the second gate portion has an upper surface including a second source-side end located toward the source electrode and a second drain-side end located toward the second drain electrode,
the second gate electrode has a lower surface including a second source-side electrode end located toward the source electrode and a second drain-side electrode end located toward the second drain electrode,
the upper surface of the first gate portion includes
a first side-space region extending over length L1 corresponding to a distance between the first source-side end and the first source-side electrode end, and
a second side-space region extending over length L2 corresponding to a distance between the first drain-side end and the first drain-side electrode end, the upper surface of the second gate portion includes
a third side-space region extending over length L3 corresponding to a distance between the second source-side end and the second source-side electrode end, and
a fourth side-space region extending over length L4 corresponding to a distance between the second drain-side end and the second drain-side electrode end,
the length L1 and the length L2 satisfy a relationship of L1>L2, and
the length L3 and the length L4 satisfy a relationship of L3>L4.

2. The semiconductor device according to claim 1, wherein:
the length L1 and the length L2 satisfy a relationship of L1≥2×L2; and
the length L3 and the length L4 satisfy a relationship of L3≥2×L4.

3. The semiconductor device according to claim 1, wherein:
the first gate portion has thickness T1 from the upper surface of the first gate portion to a lower surface of the first gate portion;
the second gate portion has thickness T2 from the upper surface of the second gate portion to a lower surface of the second gate portion;
the length L1 and the thickness T1 satisfy a relationship of L1≤T1; and
the length L3 and the thickness T2 satisfy a relationship of L3≤T2.

4. The semiconductor device according to claim 1, wherein:
the first gate electrode has length LG1 from the first source-side electrode end to the first drain-side electrode end;
the second gate electrode has length LG2 from the second source-side electrode end to the second drain-side electrode end;
the length L1, the length L2, and the length LG1 satisfy a relationship of LG1≥L1+L2; and
the length L3, the length L4, and the length LG2 satisfy a relationship of LG2≥L3+L4.

5. The semiconductor device according to claim 1, wherein:
the first gate portion includes
a first ridge including the upper surface of the first gate portion,
a first source-side horizontal extension extending horizontally from the first ridge toward the source electrode, and
a first drain-side horizontal extension extending horizontally from the first ridge toward the first drain electrode; and
the second gate portion includes
a second ridge including the upper surface of the second gate portion,
a second source-side horizontal extension extending horizontally from the second ridge toward the source electrode, and
a second drain-side horizontal extension extending horizontally from the second ridge toward the second drain electrode.

6. The semiconductor device according to claim 5, wherein:
the first source-side horizontal extension extends from the first ridge toward the source electrode over length L5;
the first drain-side horizontal extension extends from the first ridge toward the first drain electrode over length L6;
the second source-side horizontal extension extends from the second ridge toward the source electrode over length L7;
the second drain-side horizontal extension extends from the second ridge toward the second drain electrode over length L8;
the length L5 and the length L6 satisfy a relationship of L5>L6; and
the length L7 and the length L8 satisfy a relationship of L7>L8.

7. The semiconductor device according to claim 6, wherein
the length L5 and the length L6 satisfy a relationship of L6<L5≤2×L6; and
the length L7 and the length L8 satisfy a relationship of L8<L7≤2×L8.

8. The semiconductor device according to claim 6, wherein:
the length L5 and the length L7 satisfy a relationship of L5=L7; and
the length L6 and the length L8 satisfy a relationship of L6-L8.

9. The semiconductor device according to claim 5, wherein:
the first ridge and the second ridge contain the acceptor impurities at a first concentration; and
the first source-side horizontal extension, the first drain-side horizontal extension, the second source-side horizontal extension, and the second drain-side horizontal extension contain the acceptor impurities at a second concentration that is less than the first concentration.

10. The semiconductor device according to claim 1, wherein:
the first semiconductor layer is a GaN layer;
the second semiconductor layer is an AlGaN layer; and
the first gate portion and the second gate portion are each a GaN layer containing the acceptor impurities.

11. The semiconductor device according to claim 1, wherein:
the first gate electrode forms a Schottky junction with the first gate portion; and
the second gate electrode forms a Schottky junction with the second gate portion.

12. The semiconductor device according to claim 1, wherein:
the first semiconductor layer, the second semiconductor layer, the first gate portion, the first gate electrode, the source electrode, and the first drain electrode form a first field-effect transistor;
the first semiconductor layer, the second semiconductor layer, the second gate portion, the second gate electrode, the source electrode, and the second drain electrode form a second field-effect transistor; and
the first field-effect transistor and the second field-effect transistor are of a normally-off type.

13. The semiconductor device according to claim 1, wherein:
the length L1 and the length L3 satisfy a relationship of L1=L3; and
the length L2 and the length L4 satisfy a relationship of L2=L4.

14. A semiconductor device, comprising:
a substrate;
a first semiconductor layer arranged above the substrate;
a second semiconductor layer arranged on the first semiconductor layer to generate two-dimensional electron gas in the first semiconductor layer proximate to an interface of the first semiconductor layer and the second semiconductor layer;
a source electrode arranged on the second semiconductor layer;
a first gate portion formed by a third semiconductor layer containing acceptor impurities, the first gate portion being arranged on the second semiconductor layer;
a second gate portion formed by the third semiconductor layer containing the acceptor impurities, the second gate portion being arranged on the second semiconductor layer at a side of the source electrode opposite the first gate portion;
a first gate electrode arranged on part of the first gate portion;
a second gate electrode arranged on part of the second gate portion;
a first drain electrode arranged on the second semiconductor layer at a side of the first gate portion opposite the source electrode; and
a second drain electrode arranged on the second semiconductor layer at a side of the second gate portion opposite the source electrode, wherein
the first gate portion includes
a first ridge,
a first source-side horizontal extension extending horizontally from the first ridge toward the source electrode over length L5, and
a first drain-side horizontal extension extending horizontally from the first ridge toward the first drain electrode over length L6,
the second gate portion includes
a second ridge,
a second source-side horizontal extension extending horizontally from the second ridge toward the source electrode over length L7, and
a second drain-side horizontal extension extending horizontally from the second ridge toward the second drain electrode over length L8,
the length L5 and the length L6 satisfy a relationship of L5>L6, and
the length L7 and the length L8 satisfy a relationship of L7>L8.

15. The semiconductor device according to claim 14, wherein:
the length L5 and the length L6 satisfy a relationship of L6<L5≤2×L6; and
the length L7 and the length L8 satisfy a relationship of L8<L7≤2×L8.

16. The semiconductor device according to claim 14, wherein:
the length L5 and the length L7 satisfy a relationship of L5=L7; and
the length L6 and the length L8 satisfy a relationship of L6=L8.

17. The semiconductor device according to claim 14, wherein:
the first ridge and the second ridge contain the acceptor impurities at a first concentration; and
the first source-side horizontal extension, the first drain-side horizontal extension, the second source-side horizontal extension, and the second drain-side horizontal extension contain the acceptor impurities at a second concentration that is less than the first concentration.

18. The semiconductor device according to claim 14, wherein:
the first semiconductor layer is a GaN layer;
the second semiconductor layer is an AlGaN layer; and
the first gate portion and the second gate portion are each a GaN layer containing the acceptor impurities.

19. The semiconductor device according to claim 14, wherein:
the first gate electrode forms a Schottky junction with the first gate portion; and
the second gate electrode forms a Schottky junction with the second gate portion.

20. The semiconductor device according to claim 14, wherein:
the first semiconductor layer, the second semiconductor layer, the first gate portion, the first gate electrode, the source electrode, and the first drain electrode form a first field-effect transistor;
the first semiconductor layer, the second semiconductor layer, the second gate portion, the second gate electrode, the source electrode, and the second drain electrode form a second field-effect transistor; and
the first field-effect transistor and the second field-effect transistor are of a normally-off type.
